(19) United States
(12) Patent Application Publication
(10) Pub. No.: US 2025/0043176 A1
(43) Pub. Date: Feb. 6, 2025

(54) ORGANIC ELECTROLUMINESCENT MATERIALS CONTAINING PYRENE GROUP AND ORGANIC LIGHT-EMITTING DIODES USING THE SAME

(71) Applicants: YUAN ZE UNIVERSITY, Taoyuan City (TW); TETRAHEDRON TECHNOLOGY CORPORATION, Miaoli County (TW)

(72) Inventors: Tien-Lung CHIU, Taoyuan City (TW); Man-Kit LEUNG, Taoyuan City (TW); Chia-Hsun CHEN, Taoyuan City (TW); Chen-Jun CHU, Taoyuan City (TW); Chi-Chi CHANG, Taoyuan City (TW); Yi-Ru HAUNG, Taoyuan City (TW); Jiun-Haw LEE, Taoyuan City (TW); Lian-Chun HUANG, Taoyuan City (TW); Zi-Wen SU, Taoyuan City (TW); Yuan-Zhen ZUANG, Taoyuan City (TW); Jing-Xiang HUANG, Taoyuan City (TW)

(21) Appl. No.: 18/793,218

(22) Filed: Aug. 2, 2024

(30) Foreign Application Priority Data
Aug. 4, 2023 (TW) 112129435

(51) Int. Cl. C09K 11/06; H10K 50/11; H10K 50/15; H10K 50/16; H10K 85/60; H10K 101/10

(52) U.S. Cl. CPC C09K 11/06; H10K 50/11; H10K 50/15; H10K 50/16; H10K 85/622; C09K 2211/1011; C09K 2211/1029; H10K 2101/10

(57) ABSTRACT

An organic electroluminescent material is used for a sensitizer layer of an organic light-emitting diode. The organic electroluminescent material includes a structure of the following General Formula (1):

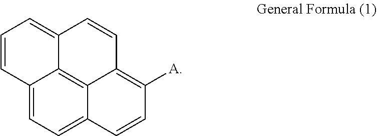

A is selected from the group consisting of General Formula (2), a carbazole group, and a substituted benzimidazole group.

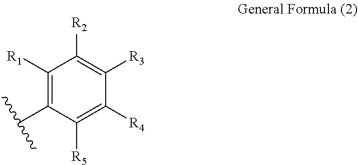

The present invention also discloses an organic light-emitting diode which has a sensitizer layer. The sensitizer layer includes a structure of General Formula (1).

### CROSS REFERENCE TO RELATED APPLICATIONS

This Non-provisional application claims priority under 35 U.S.C. §119(a) on Patent Application No(s). 112129435 filed in Taiwan, Republic of China on Aug. 4, 2023, the entire contents of which are hereby incorporated by reference.

### BACKGROUND

### Technology Field

The present disclosure relates to electroluminescent materials and light-emitting diodes by using the same and, in particular, to organic electroluminescent materials containing at least one pyrene group and organic light-emitting diodes by using the same.

### Description of Related Art

With the advancement of electronic technology, lightweight and high-efficiency flat-display devices have emerged. Organic electroluminescent devices, with their advantages of self-illumination, unrestricted viewing angles, power conservation, simple manufacturing process, low cost, high response speed, and full-color capabilities, have become the mainstream choice for flat-panel display devices.

A conventional organic light-emitting diode (OLED) consists of several stacked nano-size layers arranged in the following spatial order: an anode, a hole transport layer (HTL), a luminescent layer, an electron transport layer (ETL) and a cathode. When a voltage is applied to an OLED, a current of holes flows from the anode to the highest occupied molecular orbitals (HOMO) of the HTL, generating positive polarons. Simultaneously, a current of electrons flows from the cathode to the lowest unoccupied molecular orbitals (LUMO) of the ETL, generating negative polarons. The positive polarons and the negative polarons recombine in the luminescent layer, resulting in the generation of singlet excitons and triplet excitons. Subsequently, the singlet excitons return to the ground state, leading to the emission of light.

In the development of OLEDs, extending the lifespan of blue OLEDs has been a key concern, primarily due to the relatively high energy of blue photons, leading to rapid degradation. Specifically, active exciton-polaron annihilation occurs in blue OLEDs, as excitons possess a long lifespan and tend to react with polarons, forming high-energy polarons. These high-energy polarons easily break molecular bonds in the luminescent material, consequently reducing the lifespan of blue OLEDs.

In addition, light is emitted when singlet excitons return to the ground state. However, in fluorescent materials, triplet excitons cannot transition to siglet excitions through photon emission. This implies a considerable energy wastage, particularly when considering that triplet excitons constitute 75 percent of the excited excitons resulting from the recombination between the positive polarons and the negative polarons.

To address the aforementioned issues, in recent years, an OLED illumination mechanism based on triplet-triplet annihilation upconversion (TTAUC) has been developed. This design involves a dual-emissive layer structure where a luminescent layer is paired with a sensitizer layer. However, the development of materials for this sensitizer layer in the new structure is still unknown and requires further research and development to potentially enhance device efficiency and operational lifespan.

### SUMMARY

In view of the foregoing, an objective of the present disclosure is to provide organic electroluminescent materials containing at least one pyrene group and organic light-emitting diodes using the same, which can utilize the triplet energy within the organic light-emitting diodes to emit light, thereby enhancing the device efficiency and operational lifespan of the organic light-emitting diodes.

To achieve the above objective, the present disclosure provides an organic electroluminescent material containing at least one pyrene group, used as a sensitizer layer in an organic light-emitting diode. The organic electroluminescent material has a structure represented by General Formula (1).

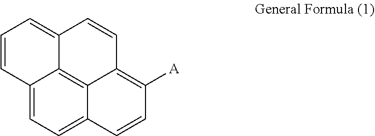

Wherein ‘A’ is selected from the group consisting of General Formula (2), a carbazole gourp, and a substituted benzimidazole group.

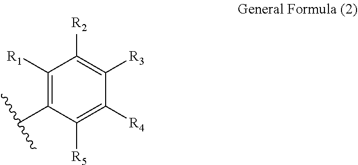

Wherein, when R₂ and R₅ are each independently selected from the group consisting of halogen, boron, nitrogen, phosphorus, oxygen, and sulfur, R₃ is a pyrene group, and R₁ and R₄ are each hydrogen.

Wherein, when R₂ and R₅ are each a carbazole group, R₃ is a pyrene group, and R₁ and R₄ are each hydrogen.

Wherein, when R₃ is

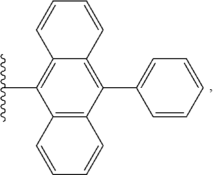 [SMILES: *c1c2ccccc2c(-c2ccccc2)c2ccccc12]

R₁, R₂, R₄, and R₅ are each hydrogen.

Wherein, when R₁ and R₅ are each alkyl, R₃ is

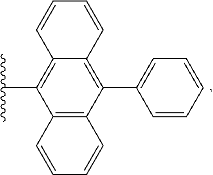 [SMILES: *c1c2ccccc2c(-c2ccccc2)c2ccccc12]

and R₂ and R₄ are each hydrogen.

Wherein, when R₁ and R₁ are each a carbazole group, R₂, R₃, and R₄ are each hydrogen.

Wherein, when R₃ is

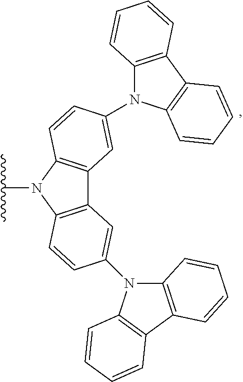 [SMILES: *n1c2ccc(-n3c4ccccc4c4ccccc43)cc2c2cc(-n3c4ccccc4c4ccccc43)ccc21]

R₁, R₂, R₄ and R₅ are each hydrogen.

Wherein, when R₁, R₃, and R₅ are each a carbazole group, R₂ and R₄ are each hydrogen.

Whewin, when R₃ is a carbazole group, R₁, R₂, R₄, and R₅ are each hydrogen.

In one embodiment, the substituted benzimidazole group is represented as

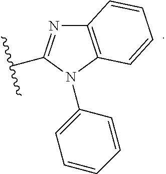 [SMILES: *c1nc2ccccc2n1-c1ccccc1]

In one embodiment, the alkyl can be a substituted straight-chain alkyl with a carbon number of 1 to 6, an unsubstituted straight-chain alkyl with a carbon number of 1 to 6, a substituted branched alkyl with a carbon number of 3 to 6, or an unsubstituted branched alkyl with a carbon number of 3 to 6.

In one embodiment, the organic electroluminescent material containing at least one pyrene group has a structure represented by the Chemical Formulas (1) to (10):

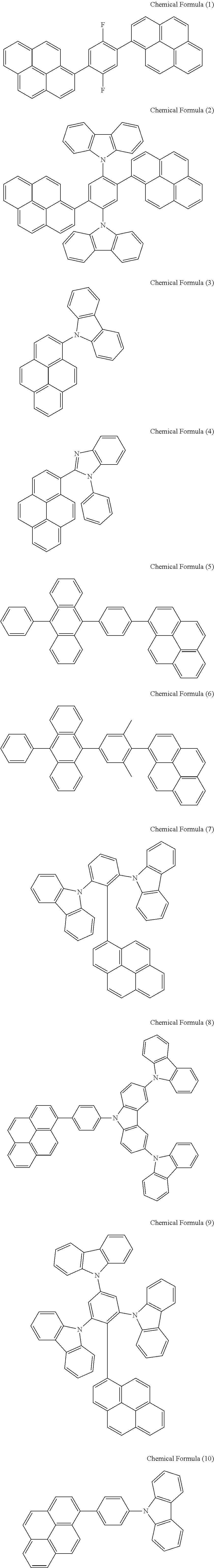

In one embodiment, the organic electroluminescent material containing at least one pyrene group is a blue fluorescent material.

To achieve the above objective, the present disclosure provides an organic light-emitting diode, includes an anode, a cathode, and a luminescent layered structure. The luminescent layered structure is positioned between the anode and the cathode. The luminescent layered structure includes a luminescent layer and a sensitizer layer. The sensitizer layer includes an organic electroluminescent material containing at least one pyrene group having a structure represented by General Formula (1).

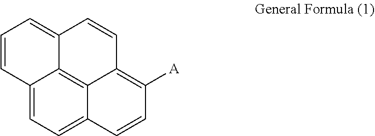

Wherein ‘A’ is selected from the group consisting of General Formula (2), a carbazole group, and a substituted benzimidazole group.

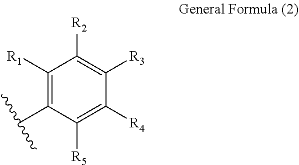

Wherein, when R₂ and R₅ are each independently selected from the group consisting of halogen, boron, nitrogen, phosphorus, oxygen, and sulfur, R₃ is a pyrene group, and R₁ and R₄ are each hydrogen.

Wherein, when R₂ and R₅ are each a carbazole group, R₃ is a pyrene group, and R₁ and R₄ are each hydrogen.

Wherein, when R₃ is

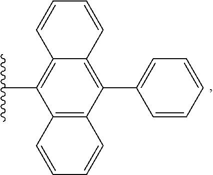 [SMILES: *c1c2ccccc2c(-c2ccccc2)c2ccccc12]

R₁, R₂, R₄, and R₅ are each hydrogen.

Wherein, when R₁ and R₅ are each alkyl, R₃ is

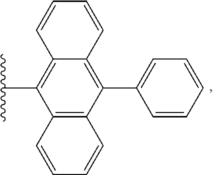 [SMILES: *c1c2ccccc2c(-c2ccccc2)c2ccccc12]

and R₂ and R₄ are each hydrogen.

Wherein, when R₁ and R₅ are each a carbazole group, R₂, R₃, and R₄ are each hydrogen.

Wherein, when R₃ is

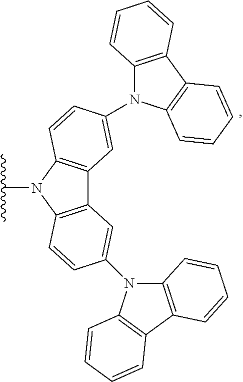 [SMILES: *n1c2ccc(-n3c4ccccc4c4ccccc43)cc2c2cc(-n3c4ccccc4c4ccccc43)ccc21]

R₁, R₂, R₄ and R₅ are each hydrogen.

Wherein, when R₁, R₃, and R₅ are each a carbazole group, and R₂ and R₄ are each hydrogen.

Whewin, when R₃ is a carbazole group, R₁, R₂, R₄, and R₅ are each hydrogen.

In one embodiment, the substituted benzimidazole group is represented as

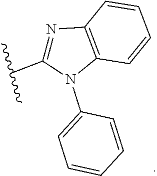 [SMILES: *c1nc2ccccc2n1-c1ccccc1]

In one embodiment, the alkyl can be a substituted straight-chain alkyl with a carbon number of 1 to 6, an unsubstituted straight-chain alkyl with a carbon number of 1 to 6, a substituted branched alkyl with a carbon number of 3 to 6, or an unsubstituted branched alkyl with a carbon number of 3 to 6.

In one embodiment, the organic electroluminescent material containing at least one pyrene group has a structure represented by the Chemical Formulas (1) to (10):

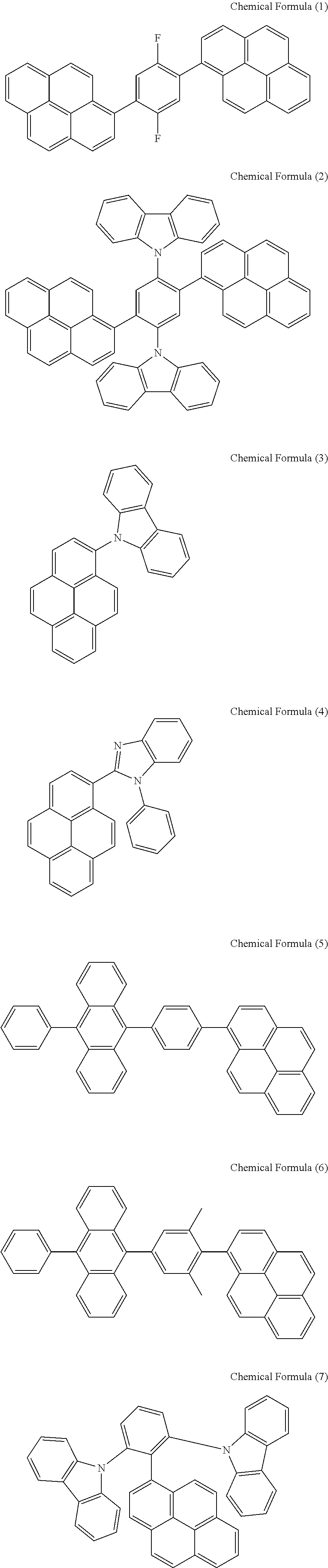

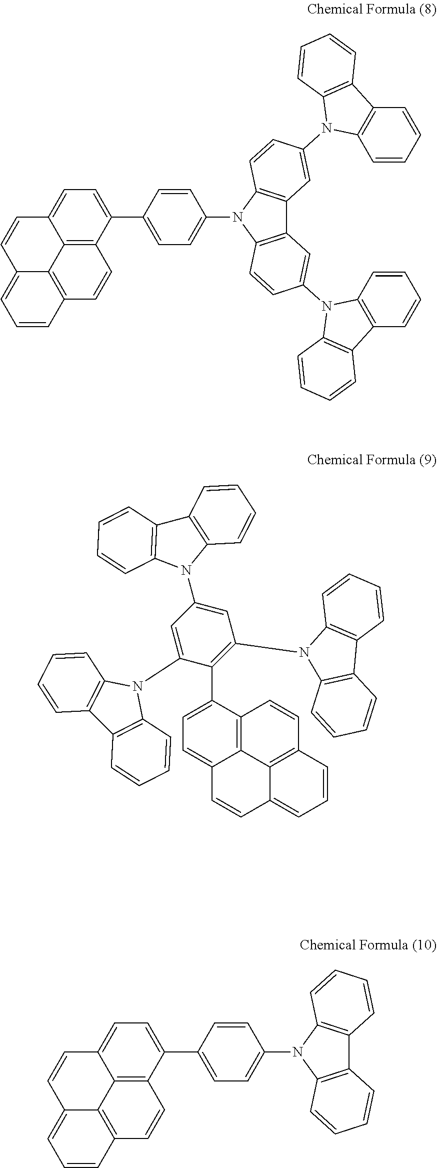 [SMILES: c1cc2ccc3ccc(-c4ccc(-n5c6ccc(-n7c8ccccc8c8ccccc87)cc6c6cc(-n7c8ccccc8c8ccccc87)ccc65)cc4)c4ccc(c1)c2c34 ; c1cc2ccc3ccc(-c4c(-n5c6ccccc6c6ccccc65)cc(-n5c6ccccc6c6ccccc65)cc4-n4c5ccccc5c5ccccc54)c4ccc(c1)c2c34 ; c1cc2ccc3ccc(-c4ccc(-n5c6ccccc6c6ccccc65)cc4)c4ccc(c1)c2c34]

In one embodiment, the luminescent layer includes a luminescent-layer ground state, a luminescent-layer singlet state, and a luminescent-layer triplet state. Two times of the luminescent-layer triplet state is higher than the luminescent-layer singlet state. The sensitizer layer includes a sensitizer-layer triplet state, wherein the sensitizer-layer triplet state is positioned between the luminescent-layer singlet state and the luminescent-layer triplet state. Molecules of the sensitizer layer at the sensitizer-layer triplet state transfer energy to molecules of the luminescent layer at the luminescent-layer triplet state and triggers triplet-triplet annihilation upconversion in the luminescent layer at the luminescent-layer triplet state such that the luminescent layer emits light of a first color.

In one embodiment, the sensitizer layer further includes a sensitizer-layer singlet state and a sensitizer-layer ground state, in which the molecules of the sensitizer layer at the sensitizer-layer singlet state return to the sensitizer-layer ground state and emit light of a second color.

In one embodiment, the organic light-emitting diode further includes a hole transport layer and an electron transport layer. The hole transport layer is disposed between the anode and the luminescent layered structure. The electron transport layer is disposed between the cathode and the luminescent layered structure.

In one embodiment, the sensitizer layer can be an electron transport layer, and the organic light-emitting diode further includes a hole transport layer disposed between the anode and the luminescent layered structure.

In one embodiment, the sensitizer layer can be a hole transport layer, and the organic light-emitting diode further includes an electron transport layer disposed between the cathode and the luminescent layered structure.

In one embodiment, the organic light-emitting diode further includes a barrier layer disposed between the sensitizer layer and the luminescent layer. The barrier layer has a barrier-layer singlet state and a barrier-layer triplet state. The barrier-layer singlet state is higher than the luminescent-layer singlet state, and the barrier-layer triplet state is higher than the luminescent-layer triplet state.

As mentioned above, the organic light-emitting diode of the present application utilizes triplet energy transfer between the sensitizer layer and the luminescent layer, triggering the triplet-triplet annihilation upconversion mechanism within the luminescent layer. This allows the triplet energy within both the luminescent layer and the sensitizer layer to participate in the light-emitting mechanism of the organic light-emitting diodes in the embodiments of the present invention. Specifically, the organic electroluminescent material containing at least one pyrene group is employed in the sensitizer layer of the organic light-emitting diode, effectively enhancing the efficiency and operational lifespan of the organic light-emitting diode.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1 is a sectional view of an organic light-emitting diode according to a second embodiment of the present invention;

FIG. 2 is a sectional view of a variant embodiment of an organic light-emitting diode according to the second embodiment of the present invention;

FIG. 3 is a sectional view of another variant embodiment of an organic light-emitting diode according to the second embodiment of the present invention;

FIG. 4 is a sectional view of an organic light-emitting diode according to a third embodiment of the present invention;

FIGS. 5 to 13 respectively illustrate external quantum efficiency-current density curves for Chemical Formulas (1) to (10) of the present invention as the sensitizer layer and various comparative examples;

FIGS. 14 to 22 respectively illustrate time-resolved electroluminescence characteristics of the organic light-emitting diodes of the present invention.

FIG. 23 is a comparative diagram of the half-life operational lifespan, illustrating the comparison of devices fabricated using the materials CbzP and BzP from the present invention as sensitizing layers, as well as the prior art compound DMPPP.

### DETAILED DESCRIPTION OF THE DISCLOSURE

Hereinafter, specific embodiments, accompanied by relevant figures, will be used to describe organic electroluminescent materials containing pyrene group and organic light-emitting diodes using the same according to the present invention, wherein the same references relate to the same elements. A person skilled in the art can understand the advantages and effects of the present invention from the description disclosed below. However, the content disclosed below is not intended to limit the protection scope of the present invention. The present invention can be implemented by a person skilled in the art based on different perspectives and applications without departing from the concept and spirit of the present invention. In addition, it should be stated in advance that the accompanying drawings of the present invention are merely used for illustration, and are not drawn according to actual dimensions for sake of clear illustration. Moreover, the same reference number corresponds to the same component. It should also be understood that expressions such as one component is “connected to” or “disposed on” another may mean that the former is either directly or indirectly connected to or disposed on the latter, wherein “connected” may refer to either physical or electrical connection.

### Organic Electroluminescent Materials Containing at Least One Pyrene Group

A first embodiment of the present disclosure provides an organic electroluminescent material containing at least one pyrene group, comprising a structure of the following General Formula (1):

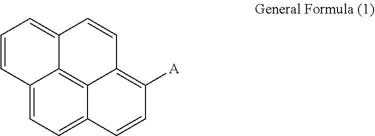

Wherein ‘A’ is selected from the group consisting of General Formula (2), a carbazole group, and a substituted benzimidazole group.

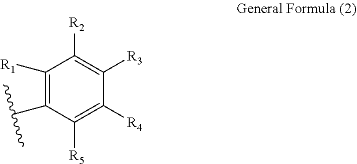

Wherein, when R₂ and R₅ are each independently selected from the group consisting of halogen, boron, nitrogen, phosphorus, oxygen, and sulfur, R₃ is a pyrene group, and R₁ and R₄ are each hydrogen.

Wherein, when R₂ and R₅ are each a carbazole group, R₃ is a pyrene group, and R₁ and R₄ are eachhydrogen.

Wherein, when R₃ is

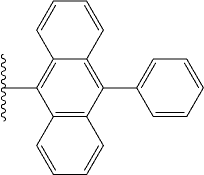 [SMILES: *c1c2ccccc2c(-c2ccccc2)c2ccccc12]

R₁, R₂, R₄, and R₅ are each hydrogen.

Wherein, when R₁ and R₅ are each alkyl, R₃ is

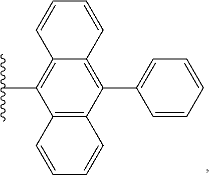 [SMILES: *c1c2ccccc2c(-c2ccccc2)c2ccccc12]

and R₂ and R₄ are each hydrogen.

Wherein, when R₁ and R₅ are each a carbazole group, and R₂, R₃, and R₄ are each hydrogen.

Wherein, when R₃ is

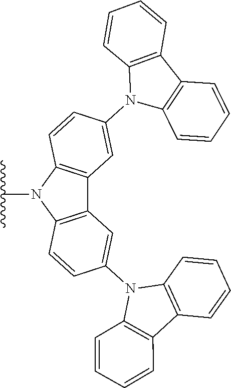 [SMILES: *n1c2ccc(-n3c4ccccc4c4ccccc43)cc2c2cc(-n3c4ccccc4c4ccccc43)ccc21]

R₁, R₂, R₄ and R₅ are each hydrogen.

Wherein, when R₁, R₃, and R₅ are each a carbazole group, R₂ and R₄ are each hydrogen.

Whewin, when R₃ is a carbazole group, R₁, R₂, R₄, and R₅ are each hydrogen.

Herein, the substituted benzimidazole group is represented as

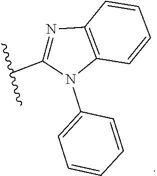 [SMILES: *c1nc2ccccc2n1-c1ccccc1]

Herein, the alkyl can be a substituted straight-chain alkyl with a carbon number of 1 to 6, an unsubstituted straight-chain alkyl with a carbon number of 1 to 6, a substituted branched alkyl with a carbon number of 3 to 6, or an unsubstituted branched alkyl with a carbon number of 3 to 6.

In this embodiment, the General Formula (1) can serve as a material for a sensitizer layer in an organic light-emitting diode. A preferred example is when ‘A’ is represented by the General Formula (2), with R₂ and R₅ being fluorine, and R₃ being a pyrene group, and R₁ and R₄ being hydrogen, denoted as Chemical Formula (1).

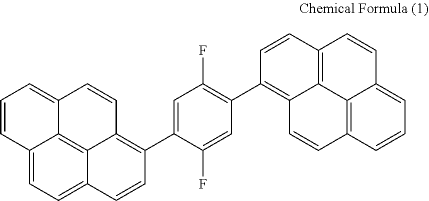

Alternatively, a preferred example is when ‘A’ is represented by General Formula (2), with R₂ and R₅ being carbazole groups, R₃ being a pyrene group, and R₁ and R₄ being hydrogen, denoted as Chemical Formula (2).

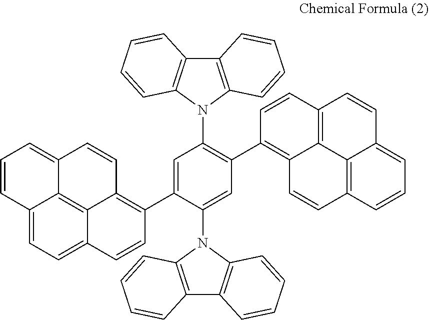

Alternatively, a preferred example is when ‘A’ is a carbazole group, that is, Chemical Formula (3).

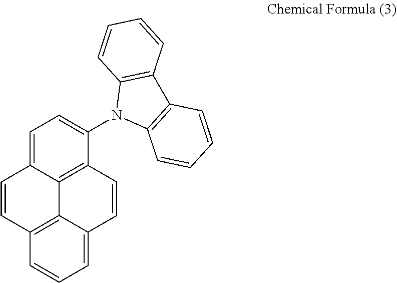 [SMILES: c1cc2ccc3ccc(-n4c5ccccc5c5ccccc54)c4ccc(c1)c2c34]

Alternatively, a preferred example is when ‘A’ is a substituted benzimidazole group, that is, Chemical Formula (4).

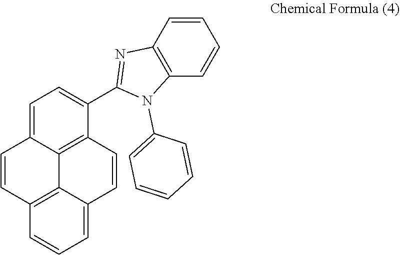 [SMILES: c1ccc(-n2c(-c3ccc4ccc5cccc6ccc3c4c56)nc3ccccc32)cc1]

Alternatively, a preferred example is when ‘A’ is represented by General Formula (2), with R₃ being 9-phenylanthracene, and R₁, R₂, R₄, and R₅ being hydrogen, denoted as Chemical Formula (5).

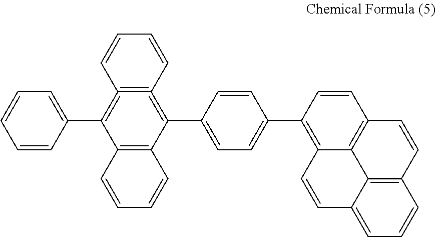

Alternatively, a preferred example is when ‘A’ is represented by the General Formula (2), with R₁ and R₅ being methyl, R₃ being 9-phenylanthracene, and R₂ and R₄ being hydrogen, denoted as Chemical Formula (6).

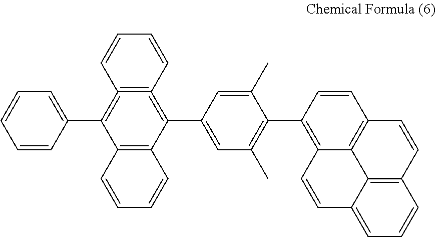

Alternatively, a preferred example is when ‘A’ is represented by the General Formula (2), with R₁ and R₅ being carbazole groups, and R₂, R₃ and R₄ being hydrogen, denoted as Chemical Formula (7).

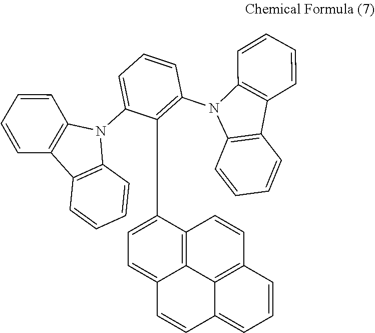

Alternatively, a preferred example is when ‘A’ is represented by the General Formula (2), with R₃ being a tricarbazole group, and R₁, R₂, R₄ and R₅ being hydrogen, denoted as Chemical Formula (8).

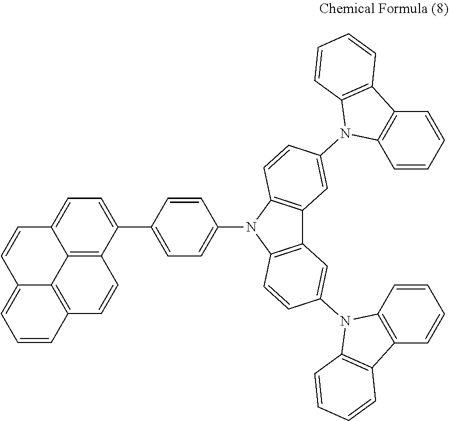

Alternatively, a preferred example is when ‘A’ is represented by the General Formula (2), with R₁, R₃ and R₅ being carbazole groups, and R₂ and R₄ being hydrogen, denoted as Chemical Formula (9).

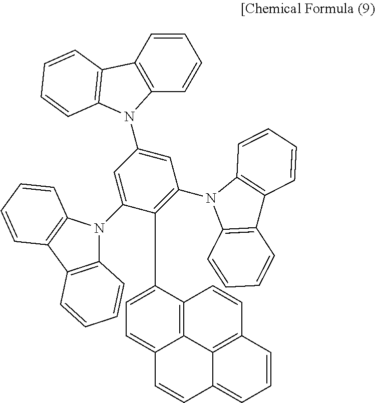

Alternatively, a preferred example is when ‘A’ is represented by the General Formula (2), with R₃ being a carbazole group, and R₁, R₂, R₄ and R₅ being hydrogen, denoted as Chemical Formula (10).

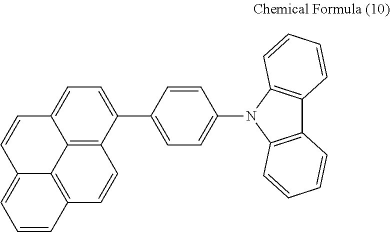

In Chemical Formulas (1) to (10), pyrene is used as the core functional group in the sensitizer layer for the organic light-emitting diodes, effectively enhancing the efficiency and operational lifespan of the organic light-emitting diodes.

In this embodiment, the organic electroluminescent material containing at least one pyrene group can be a blue fluorescent material.

### Organic Light-Emitting Diodes

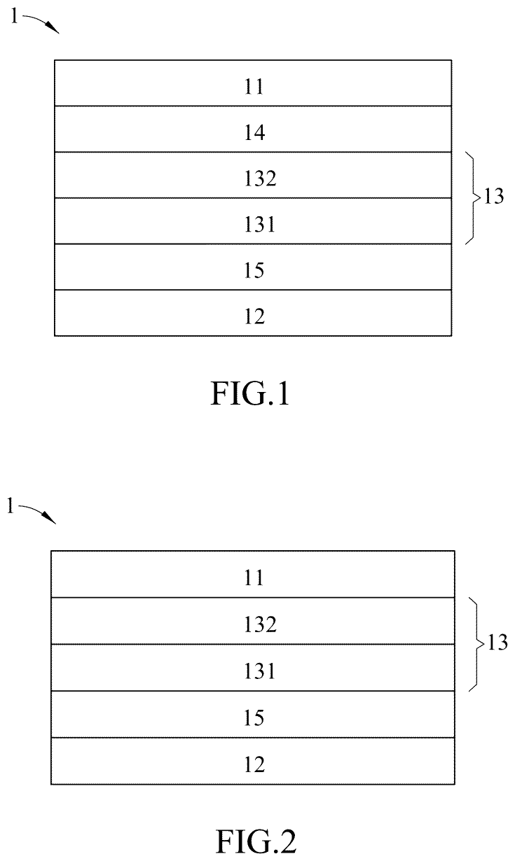

As shown in FIG. 1, a second embodiment of the present disclosure provides an organic light-emitting diode 1, including an anode 11, a cathode 12, a luminescent layered structure 13 and a hole transport layer 14 and an electron transport layer 15. The luminescent layered structure 13 is positioned between the anode 11 and the cathode 12. The hole transport layer 14 is disposed between the anode 11 and the luminescent layered structure 13, and the electron transport layer 15 is disposed between the cathode 12 and the luminescent layered structure 13.

Herein, the anode 11 can be, but is not limited to, a transparent electrode material, such as indium tin oxide (ITO). The material of the cathode 12 can be, but is not limited to, metal, a transparent conductive material, or other suitable conductive materials.

As shown in FIG. 1, the luminescent layered structure 13 includes a luminescent layer 131 and a sensitizer layer 132. The luminescent layer 13 includes a luminescent-layer ground state, a luminescent layer singlet state, and a luminescent layer triplet state. Specifically, in this embodiment, the luminescent layer 131 is a TTA (Triplet-Triplet Annihilation) material layer, meaning that two times of the luminescent-layer triplet state is higher than the luminescent-layer singlet state. Furthermore, the material of the luminescent layer 131 may include, but is not limited to, anthracene derivatives, pyrene derivatives, or perylene derivatives. Examples of such anthracene derivatives may include 9-(1-naphthalenyl)-10-(4-(2-naphthalenyl)phenyl)anthracene (NPAN), 9,10-Di(2-naphthyl)anthracene (ADN), 2-methyl-9,10-Di(2-naphthyl) anthracene, 2-tert-butyl-9,10-Di(2-naphthyl)anthracene, or 9,9′-Dianthracene.

In the embodiment of FIG. 1, the sensitizer layer 132 is positioned between the luminescent layer 131 and the hole transport layer14. However, the present invention is not limited to this configuration. In other embodiments, the positions of the luminescent layer 131 and the sensitizer layer 132 within the luminescent layered structure 13 can be swapped. In other words, in alternative embodiments, the sensitizer layer132 may be placed between the luminescent layer 131 and the electron transport layer 15. The sensitizer layer 132 includes a sensitizer-layer triplet state, wherein the sensitizer-layer triplet state is positioned between the luminescent-layer singlet state and the luminescent-layer triplet state. In this embodiment, the singlet and triplet states of the sensitizer layer 132 are respectively greater than those of the luminescent layer 131. The sensitizer layer 132 in this embodiment emits blue light, but this is only an example and not limited thereto.

Herein, the sensitizer layer 132 includes an organic electroluminescent material containing at least one pyrene group, as represented by the General Formula (1):

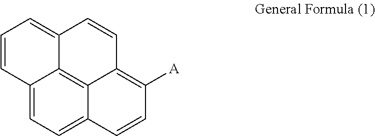

Wherein ‘A’ is selected from the group consisting of General Formula (2), a carbazole group, and a substituted benzimidazole group.

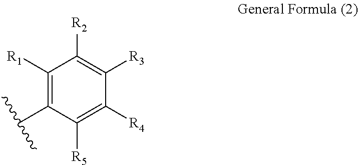

Wherein, when R₂ and R₅ are each independently selected from the group consisting of halogen, boron, nitrogen, phosphorus, oxygen, and sulfur, R₃ is a pyrene group, and R₁ and R₄ are each hydrogen.

Wherein, when R₂ and R₅ are each a carbazole group, R₃ is a pyrene group, and R₁ and R₄ are each hydrogen.

Wherein, when R₃ is

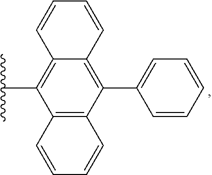 [SMILES: *c1c2ccccc2c(-c2ccccc2)c2ccccc12]

R₁, R₂, R₄, and R₅ are each hydrogen.

Wherein, when R₁ and R₅ are each alkyl, R₃ is

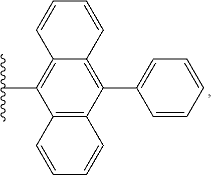 [SMILES: *c1c2ccccc2c(-c2ccccc2)c2ccccc12]

and R₂ and R₄ are each hydrogen.

Wherein, when R₁ and R₅ are each a carbazole group, and R₂, R₃, and R₄ are each hydrogen.

Wherein, when R₃ is

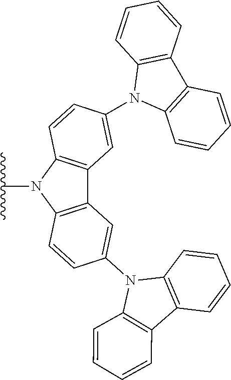 [SMILES: *n1c2ccc(-n3c4ccccc4c4ccccc43)cc2c2cc(-n3c4ccccc4c4ccccc43)ccc21]

R₁, R₂, R₄ and R₅ are each hydrogen.

Wherein, when R₁, R₃, and R₅ are each a carbazole group, R₂ and R₄ are each hydrogen.

Whewin, when R₃ is a carbazole group, R₁, R₂, R₄, and R₅ are each hydrogen.

Herein, the substituted benzimidazole group is represented as

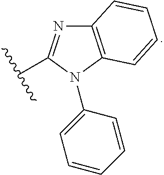 [SMILES: *c1nc2ccccc2n1-c1ccccc1]

Herein, the alkyl can be a substituted straight-chain alkyl with a carbon number of 1 to 6, an unsubstituted straight-chain alkyl with a carbon number of 1 to 6, a substituted branched alkyl with a carbon number of 3 to 6, or an unsubstituted branched alkyl with a carbon number of 3 to 6.

In the General Formula (1) of this embodiment, a preferred example is when ‘A’ is of the General Formula (2), in which R₂ and R₅ are fluorine, R₃ is a pyrene group, and R₁ and R₄ are hydrogen, which correponds to Chemical Formula (1).

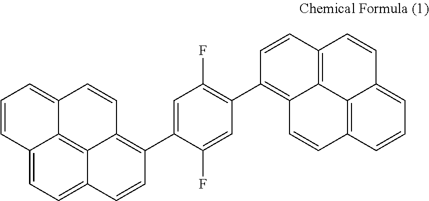

Alternatively, a preferred example is when ‘A’ is of General Formula (2), where R₂ and R₅ are carbazole groups, R₃ is a pyrene group, and R₁ and R₄ are hydrogen, which corresponds to Chemical Formula (2).

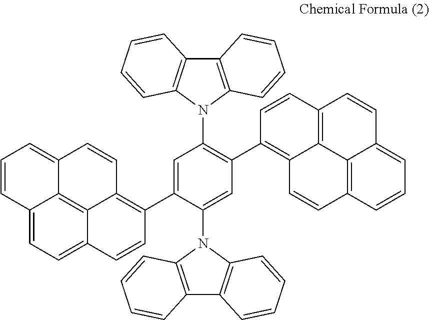

Alternatively, a preferred example is when ‘A’ is a carbazole group, that is, Chemical Formula (3).

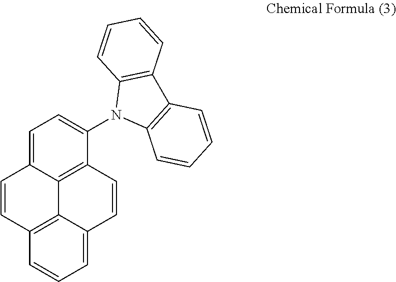 [SMILES: c1cc2ccc3ccc(-n4c5ccccc5c5ccccc54)c4ccc(c1)c2c34]

Alternatively, a preferred example is when ‘A’ is a substituted benzimidazole group, that is, Chemical Formula (4).

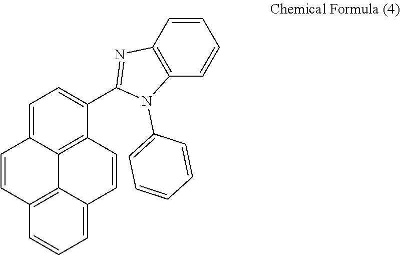 [SMILES: c1ccc(-n2c(-c3ccc4ccc5cccc6ccc3c4c56)nc3ccccc32)cc1]

Alternatively, a preferred example is when ‘A’ is of General Formula (2), where R₃ is 9-phenylanthracene, and R₁, R₂, R₄, and R₅ are hydrogen, which corresponds to Chemical Formula (5).

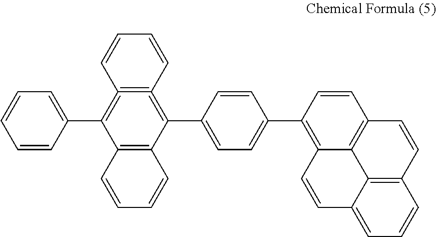

Alternatively, a preferred example is when ‘A’ is of the General Formula (2), where R₁ and R₅ are methyl, R₃ is 9-phenylanthracene, and R₂ and R₄ are hydrogen, which corresponds to Chemical Formula (6).

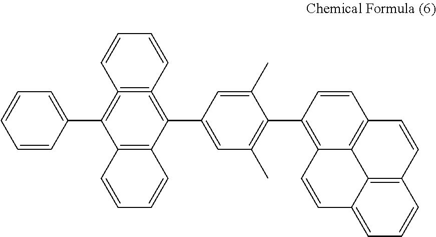

Alternatively, a preferred example is when ‘A’ is of the General Formula (2), where R₁ and R₅ are carbazole groups and R₂, R₃ and R₄ are hydrogen, which corresponds to Chemical Formula (7).

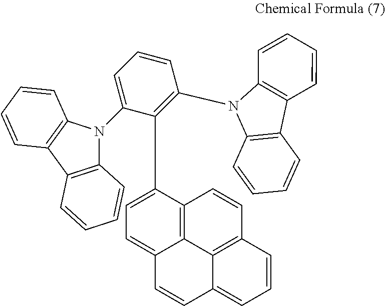

Alternatively, a preferred example is when ‘A’ is of the General Formula (2), where R₃ is a tricarbazole group, and R₁, R₂, R₄ and R₅ are hydrogen, which corresponds to Chemical Formula (8).

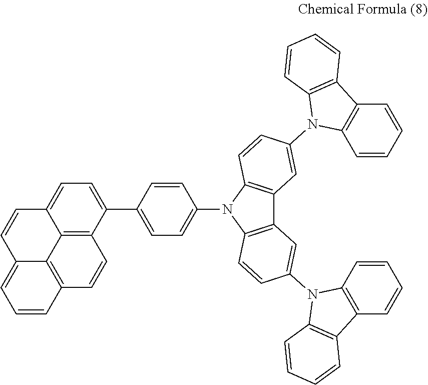

Alternatively, a preferred example is when ‘A’ is of the General Formula (2), where R₁, R₃ and R₅ are carbazole groups, and R₂ and R₄ are hydrogen, which corresponds to Chemical Formula (9).

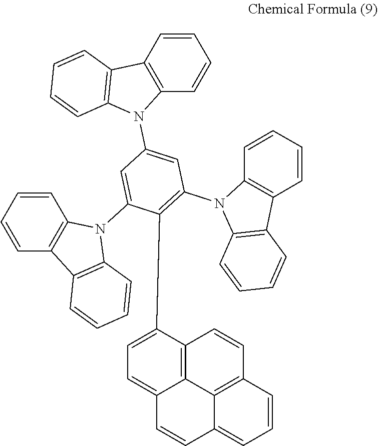

Alternatively, a preferred example is when ‘A’ is of the General Formula (2), where R₃ is a carbazole group, and R₁, R₂, R₄ and R₅ are hydrogen, which corresponds to Chemical Formula (10).

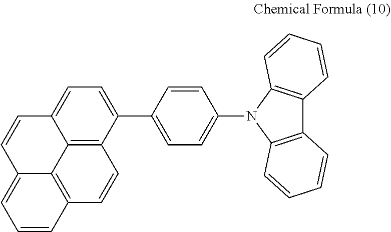

In this embodiment, by positioning the sensitizer layer 132, triplet-triplet energy transfer (TTET) occurs between the sensitizer layer 132 and the luminescent layer 131. In other words, the energy from the molecules in the triplet state of the sensitizer layer 132 is transferred to the triplet state of the luminescent layer 131, leading to triplet-triplet annihilation upconversion (TTAUC) and emitting the light of a first color (L1).

Specifically, triplet-triplet annihilation upconversion occurs between two triplet excited-state molecules in the luminescent layer 131. One of these triplet excited-state molecules transfers energy to the other, returning to the ground state, while the recipient triplet excited-state molecule transitions from the triplet state to the singlet state. The molecule in the luminescent layer 131 that undergoes this transition to the singlet state returns to the ground state of the luminescent layer 131, emitting the light of the first color (L1).

Additionally, in the sensitizer layer 132 of this embodiment, molecules at the singlet state of the sensitizer layer 132 emit the light of a second color when returning to the ground state of the sensitizer layer 132. In this embodiment, the materials of the luminescent layer 131 and the sensitizer layer 132 can be adjusted based on the default emission color of the organic light-emitting diodes, so that the combination of the light of the first color and the light of the second color produces the default emission color. Of course, the light of the first color and the light of the second color can also be the same color.

Furthermore, the material of the hole transport layer 14 can be, but is not limited to, materials such as 1,1-Bis[4-[N,N′-di(p-tolyl)amino]phenyl]cyclohexane (TAPC), N,N-bis-(1-naphthyl)-N,N-diphenyl-1,1-biphenyl-4,4-diamine (NPB), or N-N′-diphenyl-N-N′bis(3-methylphenyl)-[1-1′-biphenyl]-4-4′-diamine (TPD). The thickness of the hole transport layer 14, for example, can be, but is not limited to, within the range of less than 100 nm.

The material of the electron transport layer 15 can be, but is not limited to, metal complexes such as Tris-(8-hydroxyquinoline)aluminum (Alq₃), bis(10-hydroxybenzo[h]quinolinato)beryllium (BeBq₂), or heterocyclic compounds such as 2-(4-Biphenylyl)-5-(4-tert-butylphenyl)-1,3,4-oxadiazole (PBD), 3-(4-Biphenylyl)-4-phenyl-5-tert-butylphenyl-1,2,4-triazole (TAZ), 2,2′,2″-(1,3,5-Benzinetriyl)-tris(1-phenyl-1-H-benzimidazole) (TPBI), diphenylbis(4-(pyridin-3-yl)phenyl)silane (DPPS), Bathophenanthroline (Bphen), and the like. In this embodiment, the thickness of the electron transport layer 15, for example, can be, but is not limited to, within the range of less than 100 nm.

Additionally, FIG. 2 illustrates a variant of the second embodiment, where the sensitizer layer 132 may also serve as a hole transport layer with hole conduction capability, positioned between the luminescent layer 131 and the anode 11.

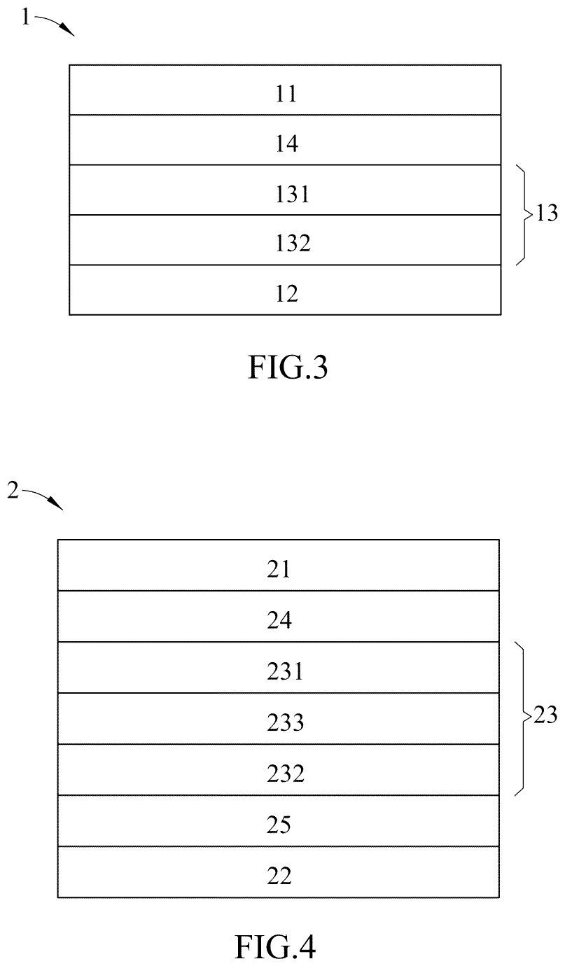

Furthermore, FIG. 3 illustrates another variation of the second embodiment, where the sensitizer layer 132 may also serve as an electron transport layer with electron conduction capability, positioned between the luminescent layer 131 and the cathode 12.

In another variation of the second embodiment, the sensitizer layer 132 can also be doped into the luminescent layer 131. The present invention is not limited to this example.

FIG. 4 depicts an organic light-emitting diode 2 according to a third embodiment of the present invention. The organic light-emitting diode 2 is similar to the organic light-emitting diode 1 of the second embodiment of the present invention, with identical elements having the same characteristics and functions, and therefore will not be reiterated. In comparison to the organic light-emitting diode 1 of the second embodiment, the main difference in the third embodiment lies in the inclusion of a barrier layer 233 between the luminescent layer 231 and the sensitizer layer 232. In this embodiment, the barrier layer 233 has a barrier-layer singlet state and a barrier-layer triplet state, where the barrier-layer singlet state is higher than the luminescent-layer singlet state, and the barrier-layer triplet state is higher than the luminescent-layer triplet state.

By incorporating the barrier layer 233, this embodiment facilitates the transfer of triplet energy from the sensitizer layer 232 to the luminescent-layer triplet state, while concurrently suppressing the quenching effect of singlet exciton generation between the sensitizer layer 232 and the luminescent layer 231. Consequently, this embodiment can further enhance the efficiency of the organic light-emitting diode 2.

Furthermore, the material of the barrier layer 233 can be, for example, 1-(2,5-dimethyl-4-(1-pyrenyl)phenyl)pyrene (DMPPP) or 1,3,5-Tri(1-pyrenyl)benzene (TPB3). However, the present application is not limited to these options.

Additionally, the organic light-emitting diode of the present invention is not limited to the configurations disclosed in the second and third embodiments; these are merely illustrative examples.

### Experimental Example

The synthesis of Chemical Formulas (1) to (10) and related compounds will be detailed with reference to multiple synthesis examples.

Synthesis of the compound dFPPP represented by Chemical Formula (1) is carried out as follows:

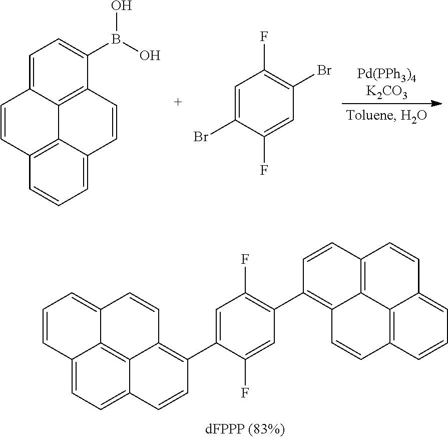 [SMILES: OB(O)c1ccc2ccc3cccc4ccc1c2c34 ; Fc1cc(Br)c(F)cc1Br ; Fc1cc(-c2ccc3ccc4cccc5ccc2c3c45)c(F)cc1-c1ccc2ccc3cccc4ccc1c2c34]

1,4-dibromo-2,5-difluorobenzene (1.32 g, 4.84 mmol), 1-Pyrenylboronic acid (2.50 g, 10.16 mmol), Tetrakis(triphenylphosphine)palladium(0) (Pd(PPh₃)₄, 0.17 g, 0.15 mmol), and Potassium carbonate (K₂CO₃, 2.68 g, 19.36 mmol) were placed in a 100 mL two-neck flask equipped with a stirring bar. After installing a condenser and a three-way valve and purged with argon for three times, deoxygenated toluene (24.2 mL, 0.2 M) and deionized water (9.7 mL, 2.0 M) were added. The mixture was heated to 110° C. and refluxed for 20 hours. After completion of the reaction, the apparatus was cooled to room temperature, and the solid was washed with n-hexane and reagent-grade acetone. The reaction mixture was filtered with suction, and the resulting solid and celite were placed in a cylindrical filter paper. After thorough mixing with a spatula, the solid was subjected to Soxhlet extraction using toluene as the solvent for 3 days. Upon returning to room temperature, a solid precipitated from the solvent. After filtered with suction, a white solid was obtained, yielding 2.36 g (95% yield)

Spectral data as follow: HRMS (m/z): [M+] calcd. for C₃₈H₂₀F₂, 514.1528; found, 514.1551; Anal. calcd. for C₃₈H₂₀F₂: C 88.70, H 3.92; found: C 88.48, H 3.96.

Synthesis of the compound dcPPPP represented by Chemical Formula (2) is carried out as follows:

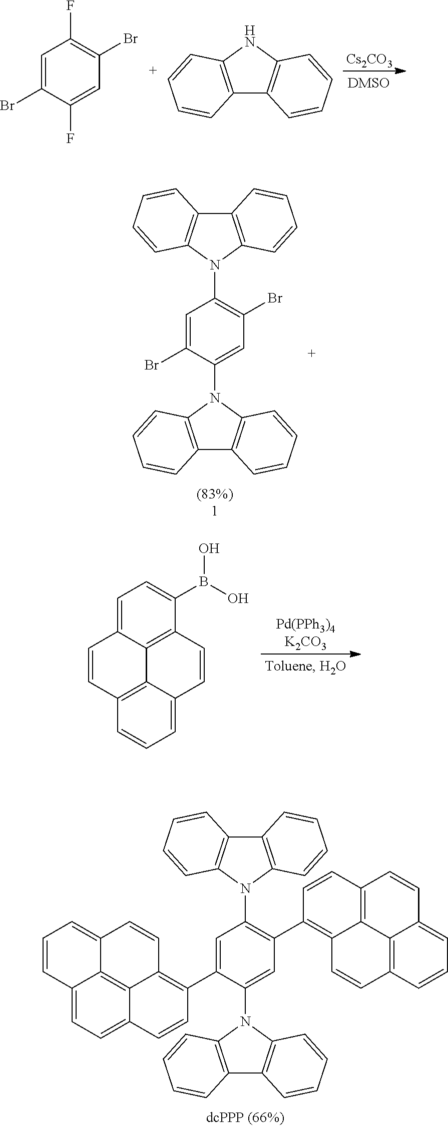

1,4-dibromo-2,5-difluorobenzene (1.00 g, 3.68 mmol), carbazole (1.54 g, 9.20 mmol), and cesium carbonate (Cs₂CO₃, 4.80 g, 14.72 mmol) were placed in a 10 mL two-neck flask equipped with a stirring bar. After installing a condenser and a three-way valve and purged with argon for three times, deoxygenated dimethyl sulfoxide (3.7 mL, 1.0 M) was added. The mixture was heated to 150° C. and refluxed for 24 hours. After completion of the reaction, the apparatus was cooled to room temperature, and the product was obtained by vacuum distillation to remove dimethyl sulfoxide, followed by extraction with dichloromethane. The organic layer was dried over anhydrous magnesium sulfate, gravity-filtered, and the solvent was removed by rotary evaporation. Finally, the product was washed with hot methanol for 2 hours, vacuum-filtered, resulting in a white solid of 1.73 g (83% yield, Product 1).

Product 1 (1.00 g, 1.77 mmol), 1-Pyrenylboronic acid (0.96 g, 3.89 mmol), Tetrakis(triphenylphosphine)palladium(0) (Pd(PPh₃)₄, 0.06 g, 0.05 mmol), and Potassium carbonate (K₂CO₃, 0.98 g, 7.08 mmol) were placed in a 25 mL two-neck flask equipped with a stirring bar. After installing a condenser and a three-way valve and purged with argon for three times, deoxygenated toluene (8.9 mL, 0.2 M) and deionized water (3.5 mL, 2.0 M) were added. The mixture was heated to 110° C. and refluxed for 20 hours. After completion of the reaction, the apparatus was cooled to room temperature, and the solid was washed with n-hexane and reagent-grade acetone. The reaction mixture was filtered with suction, and the resulting solid and celite were placed in a cylindrical filter paper. After thorough mixing with a spatula, the solid was subjected to Soxhlet extraction using dichloromethane as the solvent for 2 days. Upon returning to room temperature, a solid precipitated from the solvent. After vacuum filtration, the solid was collected. Using the same method but with o-dichlorobenzene as the solvent, Soxhlet extraction was performed for another 2 days. After returning to room temperature and cooling in an ice bath, solid precipitated from the solvent. After vacuum filtration, a white solid was obtained, yielding 0.95 g (67% yield).

Spectral data as follow: HRMS (m/z): [M+] calcd. for C₆₂H₃₆N₂, 808.2873; found, 808.2891; Anal. calcd. for C₆₂H₃₆N₂: C 92.05, H 4.49, N 3.46; found: C 91.90, H 4.43, N 3.37.

Synthesis of the compound CbzP represented by Chemical Formula (3) involves the following steps:

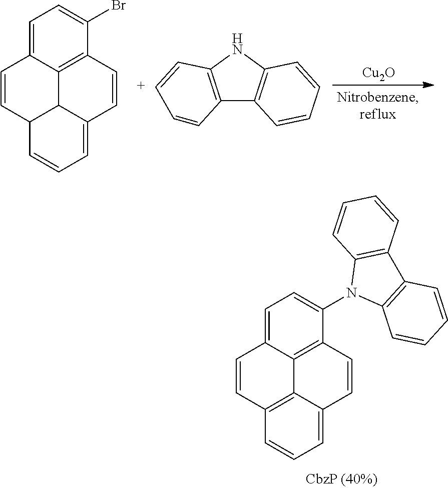

Copper(I) oxide, serving as the catalyst for the copper reagent, is initially reduced to copper (Copper(0)). 1-bromopyrene and carbazole undergo oxidative addition, utilizing deoxygenated and dehydrated nitrobenzene as a solvent. The Ullmann-type coupling reaction is conducted in an argon environment, refluxing at 250° C. for 42 hours. After completion of the reaction, the product is extracted and then purified using column chromatography, resulting in a 40% yield of the target compound CbzP.

Spectral data as follow: ¹H NMR (400 MHz, CDCl₃) δ 8.35 (d, J=8.1 Hz, 1H), 8.28-8.24 (m, 3H), 8.20-8.17 (m, 3H), 8.10-8.03 (m, 2H), 7.93 (d, J=9.2 Hz, 1H), 7.45 (d, J=9.2 Hz, 1H), 7.35-7.30 (m, 4H), 7.03-7.01 (m, 2H), ¹³C NMR (100 MHz, CDCl₃) δ 198.53, 142.62, 131.57, 131.29, 131.17, 131.13, 128.85, 128.77, 128.40, 127.34, 126.72, 126.64, 126.17, 125.96, 125.88, 125.69, 124.75, 123.49, 122.78, 120.53, 120.04, 110.39. HR-FAB m/z calcd for C₂₈H₁₇N 367.1361, not observed (M+1⁺).

Synthesis of the compound BzP represented by Chemical Formula (4) is carried out as follows:

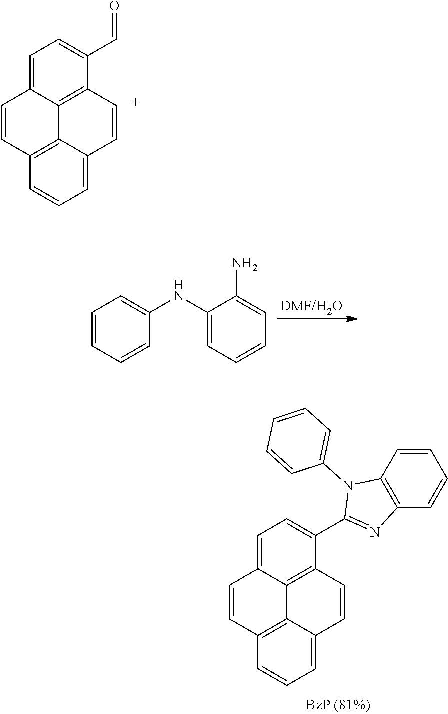 [SMILES: O=Cc1ccc2ccc3cccc4ccc1c2c34 ; Nc1ccccc1Nc1ccccc1 ; c1ccc(-n2c(-c3ccc4ccc5cccc6ccc3c4c56)nc3ccccc32)cc1]

Pyrene-1-carbaldehyde (1.00 g, 4.34 mmol) and N1-phenylbenzene-1,2-diamine (0.840 g, 4.56 mmol) were added to a solvent (8.68 mL, 0.5 M, dimethylformamide/water=9:1) and reacted at 80° C. for one day. A dark reddish-brown solid is precipitated. The solid and the filtrate were separated. The solid was purified using column chromatography (SiO₂, DCM). After removing solvents via rotary evaporation and drying under vacuum, the solid was then washed with a small amount of reagent-grade acetone, followed by suction filtration to separate the reddish-brown filtrate from the solid. The compound BzP was obtained as a light yellow powder with a yield of 87%.

Spectral data as follow: ¹H NMR (400 MHz, CDCl₃) δ 8.42 (d, J=9.2 Hz, 1H), 8.20 (t, J=7.5 Hz, 2H), 8.09 (dd, J=13.1, 8.8 Hz, 2H), 8.04-8.00 (m, 4H), 7.87 (d, J=7.9 Hz, 1H), 7.47-7.41 (m, 2H), 7.39-7.34 (m, 1H), 7.22-7.19 (m, 5H), ¹³C NMR (100 MHz, CDCl₃) δ 152.47, 143.54, 136.64, 136.39, 132.14, 131.31, 130.94, 130.65, 129.60, 128.76, 128.70, 128.61, 128.09, 127.39, 126.90, 126.38, 125.84, 125.78, 125.10, 124.86, 124.73, 124.53, 124.19, 123.66, 123.22, 120.34, 110.76. HR-FAB m/z calcd for C₂₉H₁₈N₂ 394.1470, obsd. 395.1554 (M+1⁺).

Synthesis of the compound PPA represented by Chemical Formula (5) is carried out as follows:

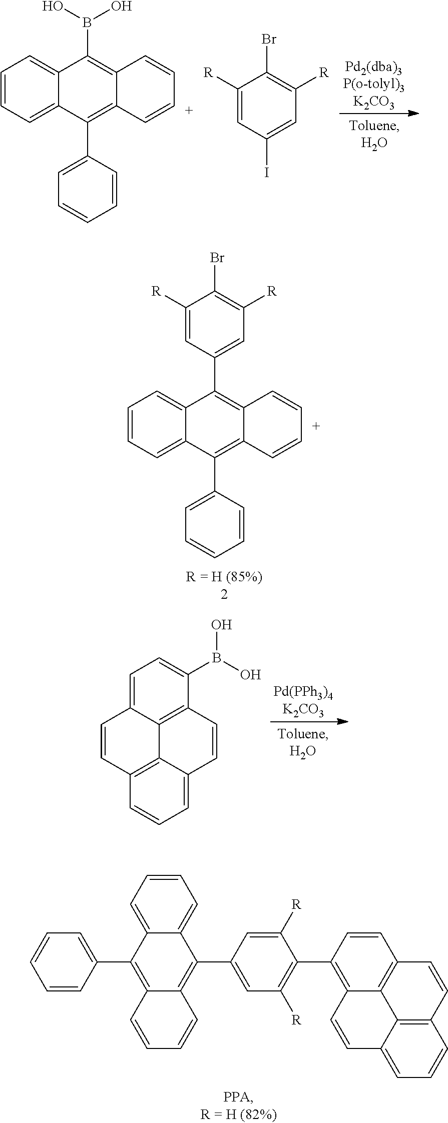

10-phenylanthracen-9-yl boronic acid (2.98 g, 10.0 mmol), 1-bromo-4-iodobenzene (2.83 g, 10.0 mmol), tris(dibenzylideneacetone)dipalladium(0) (Pd₂(dba)₃, 0.92 g, 1.00 mmol), tri(o-tolyl)phosphine (P(o-tolyl)₃, 0.92 g, 1.50 mmol), and potassium carbonate (K₂CO₃, 5.53 g, 40.0 mmol) were placed in a 250 mL two-neck flask equipped with a stirring bar. After installing a condenser and a three-way valve and purged with argon for three times, deoxygenated toluene (50 mL, 0.2 M) and deionized water (20 mL, 2.0 M) were added. The mixture was heated to 110° C. and refluxed for 20 hours. After completion, cool the reaction apparatus to room temperature, remove toluene by rotary evaporation, extract with dichloromethane, dry the organic layer with anhydrous magnesium sulfate, perform a gravity filtration, and then remove the solvent by rotary evaporation. Finally, the solid was washed with hot reagent-grade acetone for 2 hours, suction-filtered, yielding a white solid (3.47 g, 85% yield), designated as product 2.

Product 2 (1.5 g, 3.66 mmol), 1-Pyrenylboronic acid (1.08 g, 4.40 mmol), Tetrakis(triphenylphosphine)palladium(0) (Pd(PPh₃)₄, 0.21 g, 0.18 mmol), and potassium carbonate (K₂CO₃, 2.02 g, 14.64 mmol) were placed in a 50 mL two-neck flask equipped with a stirring bar. After installing a condenser and a three-way valve and purged with argon for three times, deoxygenated toluene (18.3 mL, 0.2 M) and deionized water (7.3 mL, 2.0 M) were added. The mixture was heated to 110° C. and refluxed for 24 hours. After completion, the apparatus was cooled to room temperature, and the toluene was removed by rotary evaporation. The residue was extracted with dichloromethane, and the organic layer was dried over anhydrous magnesium sulfate, gravity-filtered, and then concentrated by rotary evaporation. The crude product was purified by column chromatography (eluent:Hexane: DCM=10:1), yielding a light yellow solid (1.6 g, 82% yield).

Spectral data as follow: ¹H NMR (400 MHz, DMSO-d⁶): δ=8.45 (d, J=9.2 Hz, 1H), 8.31 (d, J=7.8 Hz, 1H), 8.23-8.21 (m, 2H), 8.18 (d, J=7.8 Hz, 1H), 8.16-8.11 (m, 3H), 8.04 (t, J=7.6 Hz, 1H), 7.93-7.87 (m, 4H), 7.74 (d, J=8.4 Hz, 2H), 7.68 (d, J=8.0 Hz, 2H), 7.64-7.60 (m, 2H), 7.57 (d, J=7.2 Hz, 1H), 7.51 (d, J=6.6 Hz, 2H), 7.45-7.36 (m, 4H); ¹³C NMR (400 MHz, DMSO-d⁶): δ=140.32, 139.07, 138.01, 137.49, 137.27, 136.82, 131.53, 131.38, 131.33,131.03, 130.70, 130.63, 130.00, 129.95, 128.58, 128.43, 127.80, 127.63, 127.50, 127.47,127.07, 127.02, 126.06, 125.37, 125.18, 125.16, 125.09, 124.98, 124.91, 124.78; Anal.calcd. for C₄₂H₂₆: C 95.06, H 4.94; found: C 94.91, H 5.04.

Synthesis of the compound dmPPA represented by Chemical Formula (6) is carried out as follows:

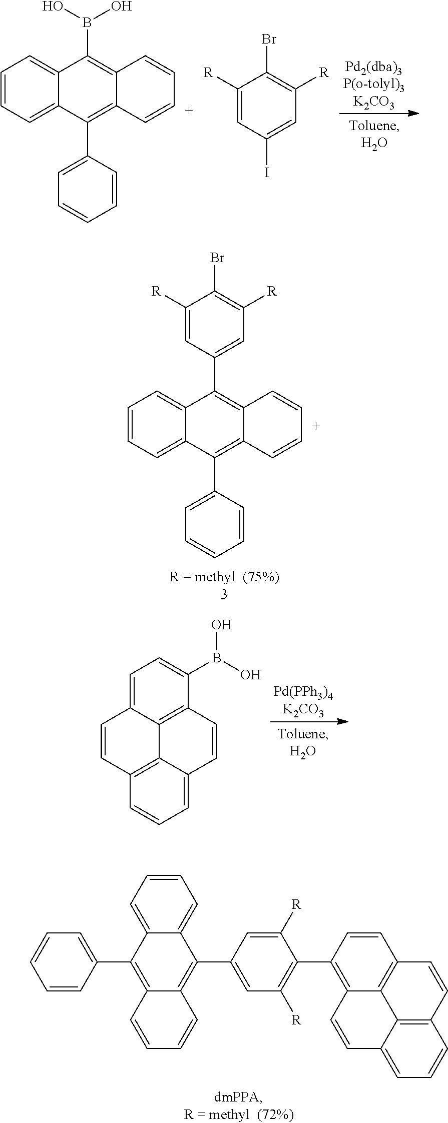

10-phenylanthracen-9-yl boronic acid (3.02 g, 10.10 mmol), 2-bromo-1,3-dimethyl-5-iodobenzene (3.00 g, 9.65 mmol), Tris(dibenzylideneacetone)dipalladium(0) (Pd₂(dba)₃, 0.74 g, 0.81 mmol), Tri(o-tolyl)phosphine (P(o-tolyl)₃, 0.74 g, 2.43 mmol), and potassium carbonate (K₂CO₃, 5.53 g, 40.00 mmol) were placed in a 250 mL two-neck flask equipped with a stirring bar. After installing a condenser and a three-way valve and purged with argon for three times, deoxygenated toluene (50.5 mL, 0.2 M) and deionized water (20 mL, 2.0 M) were added. The reaction mixture was heated to reflux at 110° C. for 20 hours. After completion, the apparatus was cooled to room temperature, and the toluene was removed by rotary evaporation. The residue was extracted with dichloromethane, and the organic layer was dried over anhydrous magnesium sulfate, gravity-filtered, and then concentrated by rotary evaporation. The crude product was washed with hot reagent-grade acetone for 2 hours, and after suction filtration, a light yellow solid was obtained (3.14 g, 75% yield), which is product 3.

Product 3 (0.50 g, 1.15 mmol), 1-pyrenylboronic acid (1-Pyrenylboronic acid, 0.31 g, 1.26 mmol), tetrakis(triphenylphosphine)palladium(0) (Pd(PPh₃)₄, 0.07 g, 0.06 mmol), and potassium carbonate (K₂CO₃, 0.63 g, 4.59 mmol) were placed in a 25 mL two-neck flask with a stirring bar. After installing a condenser and a three-way valve and purged with argon for three times, deoxygenated toluene (5.8 mL, 0.2 M) and deionized water (2.3 mL, 2.0 M) were added. The mixture was then heated to 110° C. and refluxed for 24 hours. After completion of the reaction, the apparatus was cooled to room temperature. Toluene was removed by rotary evaporation, and the remaining mixture was extracted with dichloromethane. The organic layer was dried over anhydrous magnesium sulfate, filtered by gravity, and concentrated by rotary evaporation. Purification was performed by column chromatography (eluent is Hexane:DCM=9:1). The product was further washed with a small amount of hot acetonitrile for 1 hour, left to settle to room temperature, and then suction-filtered to obtain a white solid (0.46 g) with a yield of 72%.

Spectral data as follow: ¹H NMR (400 MHz, DMSO-d⁶): δ=8.34 (d, J=7.8 Hz, 1H), 8.22 (t, J=7.1 Hz, 2H), 8.16 (dt, J=6.6, 9.0 Hz, 2H), 8.10 (d, J=9.2 Hz, 1H), 8.06-7.96 (m, 4H), 7.85 (d, J=9.2 Hz, 1H), 7.73 (m, 2H), 7.64-7.58 (m, 3H), 7.53-7.47 (m, 3H), 7.45-7.36 (m, 3H), 2.03 (s, 6H); ¹³C NMR (400 MHz, DMSO-d⁶): δ=139.23, 139.18, 138.15, 137.46, 137.11, 136.95, 136.37, 131.42, 131.38, 131.20, 130.53, 130.29, 129.99, 129.98, 129.95, 128.93, 128.42, 127.81, 127.52, 127.45, 127.31, 127.30, 127.27, 127.26, 127.03, 126.99, 126.02, 125.14, 125.10, 125.09, 125.05, 125.03, 125.02, 124.96, 20.83; Anal. calcd. for C₄₄H₃₀: C 94.59, H 5.41; found: C 94.51, H 5.45.

Synthesis of the compound D-CbzP represented by the Chemical Formula (7) is carried out as follows:

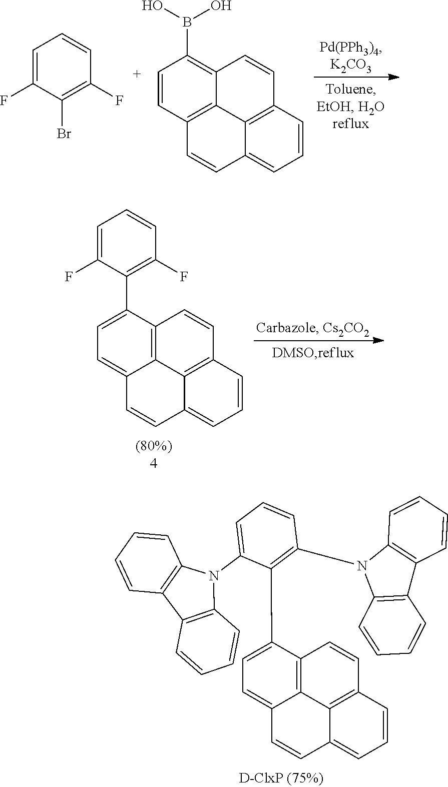

In a two-neck round-bottom flask, 2-bromo-1,3-difluorobenzene (1.00 g, 5.18 mmol), 1-pyrenylboronic acid (1.40 g, 5.70 mmol), tetrakis(triphenylphosphine)palladium (Pd(PPh₃)₄, 0.180 g, 0.1554 mmol), potassium carbonate (K₂CO₃, 0.357 g, 2.59 mmol) and solvent (10.4 mL, 0.5M, toluene/ethanol/water=10:1:2) were added. The reaction mixture was refluxed at 90° C. under an argon atmosphere for 18 hours. After completion of the reaction, the solvent was evaporated, and the organic layer was extracted with dichloromethane and water. Anhydrous magnesium sulfate was added to dry the organic layer, and excess Pd(PPh₃)₄ was filtered off through celite. The filtrate was collected, rotary-evaporated, and further purified by column chromatography (SiO₂, Hexane/DCM=9:1). The product 4 was obtained with a yield of 80%, appearing as a white powder.

Product 4 (0.500 g, 1.59 mmol), 9H-carbazole (0.617 g, 3.65 mmol) and Cesium carbonate (Cs₂CO₃, 1.20 g, 3.65 mmol) were added to Dimethyl sulfoxide (DMSO, 0.795 mL, 2M), and the reaction was refluxed at 170° C. for 18 hours. Upon completion of the reaction, the solvent was evaporated, and the organic layer was extracted with dichloromethane and water. Anhydrous magnesium sulfate was added for drying, followed by filtration. The filtrate was collected and concentrated by rotary evaporation. Subsequently, hot reagent-grade acetone was added for washing three times until the solid turned white. Suction filtration separated the deep yellow filtrate from the white powder solid. Toluene was added to the solid, heated, and refluxed to oversaturation. After cooling to room temperature, the product D-CbzP was obtained with a yield of 75% as white powder crystals.

Spectral data as follow: ¹H NMR (400 MHz, CDCl₃) δ 7.98 (d, J=9.1 Hz, 2H), 7.91-7.81 (m, 5H), 7.77-7.69 (m, 5H), 7.65 (d, J=8.9 Hz, 1H), 7.56 (d, J=7.8 Hz, 1H), 7.48 (d, J=8.9 Hz, 1H), 7.42 (d, J=9.3 Hz, 1H), 7.36-7.31 (m, 3H), 7.27-7.26 (m, 4H) 7.07-7.02 (m, 4H), 6.91 (t, J=7.4Hz, 2H); ¹³C NMR (100 MHz, CDCl₃) δ 141.35, 141.07, 140.32, 139.48, 130.85, 130.65, 130.53, 130.48, 130.46, 128.92, 128.52, 127.37, 127.10, 126.36, 125.50, 125.43, 125.09, 124.87, 124.85, 123.83, 123.75, 123.22, 123.15, 120.09, 119.99, 119.67, 119.61, 110.30, 110.23. HR-FAB m/z calcd for C₄₆H₂₈N₂ 608.2252, obsd. 608.2252 (M⁺).

Synthesis of the compound PPt represented by the Chemical Formula (8) is carried out as follows:

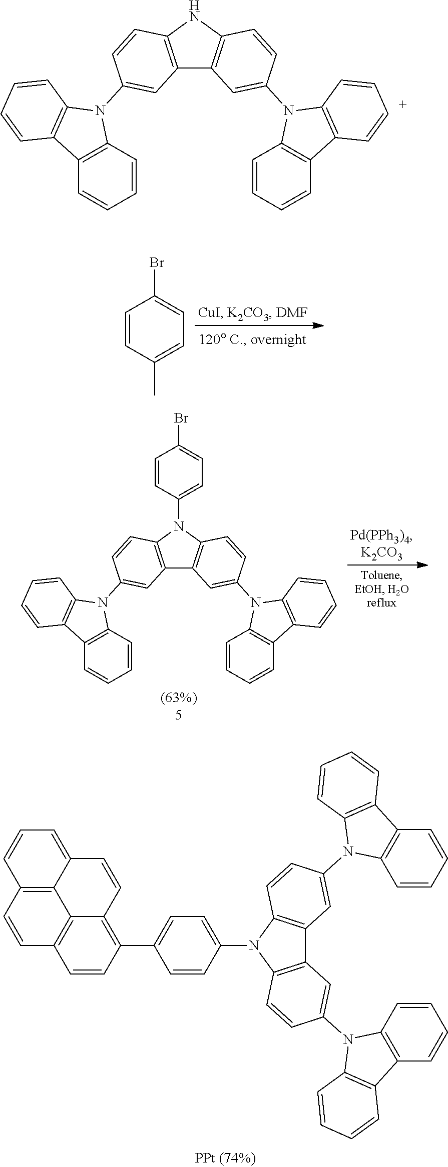

9-acetyl-3,6-diiodo carbazole (4.95 g, 10.7 mmol), carbazole (3.63 g, 21.7 mmol), and Copper(I) oxide (Cu₂O, 3.07 g, 21.5 mmol) were placed in a 25 mL two-neck flask equipped with a condenser and a three-way valve. After purged with argon for three times, deoxygenated and dehydrated dimethylacetamide (11.9 mL) was added to the flask, and the reaction proceeded at 170° C. for 16 hours under a condenser. Upon cooling to room temperature, the mixture was subjected to vacuum distillation to remove dimethylacetamide. The residue was then chromatographed through celite with dichloromethane as eluent, and the filtrate was collected. After concentrating the filtrate, Potassium hydroxide (KOH, 5.2 g, 0.092 mol) was added, with tetrahydrofuran (THF, 70 ml) as the solvent, followed by the addition of methanol (MeOH, 50 ml). The mixture was reacted at 80° C. for one hour. After completion, the solvent was removed by rotary evaporation, and the resulting mixture was washed with ethyl acetate over celite. Purification was achieved by column chromatography. The eluent ratio for washing the celite was 4:1 of hexane to ethyl acetate. The powder was then washed with dichloromethane under reflux to yield a white solid weighing 3.06 grams, with a yield of 58%.

The reaction was carried out by placing 1.62 g (5.73 mmol) of p-bromoiodobenzene, 1.34 g (2.69 mmol) of tricarbazole, 1.12 g (8.10 mmol) of Potassium carbonate, and 0.52 g (2.73 mmol) of Copper(I) iodide in a 25 mL single-neck flask. Dimethylformamide (11 ml) was added, and the mixture was refluxed at 120° C. overnight. After cooling to room temperature, the dimethylformamide was removed by distillation under reduced pressure, and the residue was washed with dichloromethane over celite. The final purification was achieved by column chromatography, resulting in a white solid weighing 1.11 g, with a yield of 63%. This is the product 5.

1-pyrenylboronic acid (0.38 g, 1.54 mmol), product 5 (0.98 g, 1.50 mmol), Potassium carbonate (0.41 g, 2.97 mmol), and tetrakis(triphenylphosphine)palladium(0) (0.17 g, 0.15 mmol) were placed in a 5 mL two-neck flask. To this mixture, a pre-prepared solution of toluene (1.0 mL), water (0.2 mL), and ethanol (0.1 mL) were added. The reaction was refluxed at 90° C. for 18 hours. After cooling to room temperature, the mixture was washed with dichloromethane over celite. The final purification was achieved by column chromatography, resulting in a pale yellow solid weighing 0.86 g, with a yield of 75%.

Spectral data as follow: ¹H NMR (400 MHz, CDCl₃): δ=8.35-8.29 (m, 4H), 8.22 (t, J=8.00 Hz, 2H), 8.18-8.11 (m, 8H), 8.04 (t, J=8.00 Hz, 1H), 7.95 (dd, J1=18.80 Hz, J2=8.40 Hz, 4H), 7.85 (d, J=8.40 Hz, 2H), 7.67 (dd, J1=8.80 Hz, J2=2.00 Hz, 2H), 7.44-7.38 (m, 8H), 7.31-7.27 (m, 4H). ¹³C NMR (400 MHz, CDCl₃): δ=141.78, 141.20, 140.71, 136.35, 136.25, 132.37, 131.50, 130.98, 130.94, 130.50, 128.55, 127.95, 127.78, 127.59, 127.40, 127.02, 126.35, 126.20, 125.91, 125.43, 125.09, 124.90, 124.87, 124.81, 124.10, 123.18, 120.32, 119.79, 119.72, 111.48, 109.71, 77.21.

Synthesis of the compound T-CbzP represented by the Chemical Formula (9) is carried out as follows:

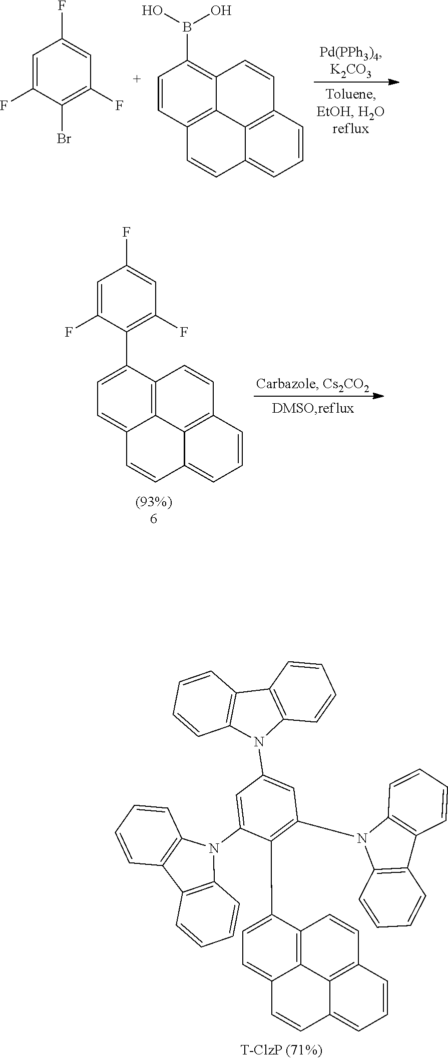

The reaction mixture of 2-Bromo-1,3,5-trifluorobenzene (1.09 g, 5.18 mmol), 1-pyrenylboronic acid (1.40 g, 5.70 mmol), tetrakis(triphenylphosphine)palladium (Pd(PPh₃)₄, 0.180 g, 0.1554 mmol), potassium carbonate (K₂CO₃, 0.357 g, 2.59 mmol), and solvent (10.4 mL, 0.5M, toluene/ethanol/water=10:1:2) were refluxed at 90° C. under argon for 18 hours. After completion of the reaction, the solvent was evaporated, and the organic layer was extracted with dichloromethane and water. Anhydrous magnesium sulfate was added for drying the organic layer, followed by filtration through celite. The filtrate was collected, rotary-evaporated, and further purified by column chromatography (SiO₂, Hexane/DCM=9:1). Compound 6 was obtained with a yield of 93%, appearing as a white powder.

0.500 g (1.50 mmol) of product 6, 0.972 g (4.96 mmol) of 9H-carbazole, and 1.63 g (4.96 mmol) of Cesium carbonate were added in a reaction flask with dimethyl sulfoxide (DMSO, 1.25 mL, 1.2M), and the reaction was refluxed at 170° C. for 18 hours. Upon completion of the reaction, the solvent was evaporated, and the organic layer was extracted with dichloromethane and water. Anhydrous magnesium sulfate was added for drying, followed by filtration. The filtrate was collected, rotary-evaporated, and subsequently hot reagent-grade acetone was added for washing three times until the solid turned white. Vacuum filtration separated the deep yellow filtrate from the white powder solid. Toluene was added to the solid, heated, and refluxed to oversaturation. After cooling to room temperature, the product T-CbzP was obtained with a yield of 71%, appearing as white powder crystals.

Spectral data as follow: ¹H NMR (400 MHz, CDCl₃) δ 8.15-8.12 (m, 5H), 7.87 (dd, J=7.4, 2.7 Hz, 2H), 7.79-7.72 (m, 7H), 7.69-7.65 (m, 2H), 7.52-7.41 (m, 9H), 7.34-7.30 (m, 4H), 7.12-7.06 (m, 4H), 6.95 (t, J=7.5Hz, 2H); ¹³C NMR (100 MHz, CDCl₃) δ 141.16, 140.91, 140.89, 140.16, 139.82, 138.58, 130.85, 130.74, 130.50, 128.68, 128.31, 127.95, 127.49, 127.33, 127.06, 126.67, 126.59, 125.76, 125.70, 125.52, 125.04, 125.02, 124.91, 124.24, 124.15, 123.98, 123.95, 123.46, 123.38, 121.08, 120.77, 120.28, 120.19, 120.04, 119.99, 110.22, 110.11, 109.89. HR-FAB m/z calcd for C58H35N3 773.2831, obsd. 774.2907 (M+1⁺).

Synthesis of the compound PPc represented by the Chemical Formula (10) is carried out as follows:

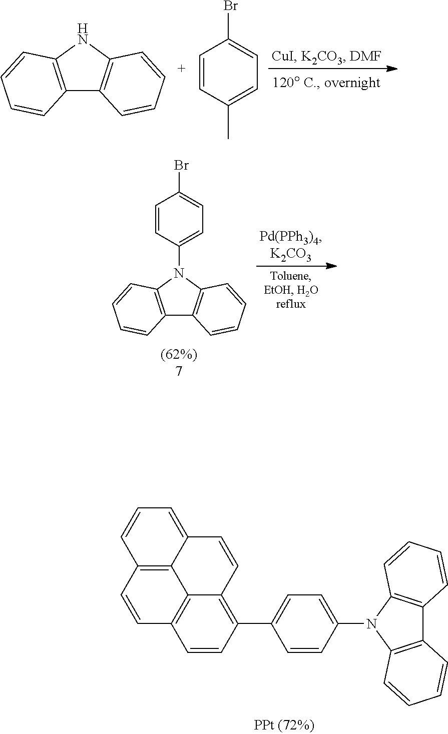

In a 25 mL single-neck flask, 1.62 g (5.73 mmol) of p-bromoiodobenzene, 0.45 g (2.69 mmol) of carbazole, 1.12 g (8.10 mmol) of Potassium carbonate, and 0.52 g (2.73 mmol) of Copper(I) iodide were placed. Dimethylformamide (11 mL) was added, and the mixture was refluxed at 120° C. overnight. After cooling to room temperature, dimethylformamide was removed by distillation under reduced pressure. The residue was washed with dichloromethane over celite. The final purification was achieved by column chromatography, resulting in a white solid weighing 0.54 g, with a yield of 62%. This is the product 7.

In a 5 mL two-neck flask, 0.38 g (1.54 mmol) of 1-pyrenylboronic acid, 0.48 g (1.50 mmol) of product 7, 0.41 g (2.97 mmol) of Potassium carbonate, and 0.17 g (0.15 mmol) of tetrakis(triphenylphosphine)palladium(0) were placed. To this mixture, a pre-prepared solution of toluene (1.0 mL), water (0.2 mL), and ethanol (0.1 mL) was added. The reaction was refluxed at 90° C. for 18 hours. After cooling to room temperature, the mixture was washed with dichloromethane over celite. The final purification was achieved by column chromatography, resulting in a pale yellow solid weighing 0.67 g, with a yield of 72%.

Spectral data as follow: ¹H NMR (400 MHz, CDCl₃): δ=8.32-8.26 (m, 4H), 8.22-8.17 (m, 4H), 8.12-8.07 (m, 4H), 8.03 (t, J=8.00 Hz, 1H), 7.85 (d, J=8.00 Hz, 2H), 7.75 (d, J=8.00 Hz, 2H), 7.59 (d, J=4.00 Hz, 2H), 7.47 (t, J=8.00 Hz, 2H), 7.32 (t, J=8.00 Hz, 2H). ¹³C NMR (400 MHz, CDCl₃): δ=144.92, 140.28, 136.93, 136.66, 131.9, 131.53, 130.98, 130.87, 128.55, 127.83, 127.67, 127.62, 127.43, 126.92, 126.13, 126.02, 125.32, 125.05, 125.03, 125.01, 124.94, 124.79, 123.50, 120.37, 120.07, 109.91.

Evaluation method for organic electroluminescent materials containing at least one pyrene group as sensitizer layer materials

Organic electroluminescent materials containing pyrene groups include compounds 1 to 10, namely, Chemical Formulas (1) to (10). The evaluation method for these materials involves investigating their thermal, electrochemical, and photophysical properties. Parameters such as thermal decomposition temperature (T_{d}), glass transition temperature (T_{g}), melting point (Tₘ), crystallization temperature (T_{c}), oxidation potential (E_{DPV}^{ox}), reduction potential (E_{DPV}^{re}), highest occupied molecular orbital energy level (E_{HOMO}), lowest unoccupied molecular orbital energy level (E_{LUMO}), energy gap (E_{g}), maximum absorption wavelength (λₘₐₓ^{abs}), maximum fluorescence emission wavelength at room temperature (λₘₐₓ^{FL}), maximum fluorescence emission wavelength at low temperature (λₘₐₓ^{LTFL}), onset absorption wavelength (λₒₙₛₑₜ^{abs}), and quantum yield (QY) are measured for the evaluation.

The stability of the surface morphology of the film during the device fabrication process plays a crucial role, and its melting point and glass transition temperature are measured by Differential Scanning Calorimetry (DSC). The thermal decomposition temperature is measured by a Thermogravimetric Analyzer (TGA). These parameters serve as criteria to assess whether the fabrication and performance of the device can be stable.

The electrochemical properties (E_{HOMO}, E_{LUMO}) of the compounds are determined using cyclic voltammetry (CV) and differential-pulse voltammetry (DPV), scanning their oxidation potential (E_{DPV}^{ox}) and reduction potential (E_{DPV}^{re}). In this experimental example, ferrocene is used as a standard, and measurements are conducted in dichloromethane solvent with a three-electrode system comprising a platinum electrode as the working electrode, a platinum wire electrode as the auxiliary electrode, and a silver/chloride silver electrode as the reference electrode for oxidation potential measurements. For reduction potential measurements, an anhydrous dimethylacetamide solvent is employed with a glassy carbon electrode as the working electrode. The energy gap (E_{g}^{sol}) represents the difference between the highest occupied molecular orbital energy level (E_{HOMO}) and the lowest unoccupied molecular orbital energy level (E_{LUMO}). E_{HOMO} and E_{LUMO} assist in identifying charge injection or charge transport materials with matching energy levels, contributing to higher device efficiency.

The maximum absorption wavelength (λₘₐₓ^{abs}), room temperature maximum fluorescence emission wavelength (λₘₐₓ^{FL}), and onset absorption wavelength (λₒₙₛₑₜ^{abs}) are measured using tetrahydrofuran (concentration of 10⁻⁵ M) as the solvent. The low-temperature maximum fluorescence emission wavelength (λ_{maxL}^{TFL}) is measured using 2-methyltetrahydrofuran (concentration of 10⁻⁵ M) as the solvent at a temperature of 77 K. Quantum yield (QY) is determined using a fluorescence spectrometer.

### The Thermal Properties of Compounds 1 to 10 (Chemical Formula (1) to Chemical Formula (10)) are Summarized in Table 1.

TABLE1

| Compounds | M.W. | T_{d} (° C.) | T_{g} (° C.) | Tₘ (° C.) | T_{c} (° C.) |
|---|---|---|---|---|---|
| Chemical Formula (1) | 514.15 | 363 | — | 347 | 301 |
| Chemical Formula (2) | 808.29 | 483 | — | >400 | — |
| Chemical Formula (3) | 367.45 | 255 | 71 | —^{b} | 296 |
| Chemical Formula (4) | 394.48 | 258 | 82 | —^{b} | 310 |
| Chemical Formula (5) | 530.20 | 375 | 130 | 309 | — |
| Chemical Formula (6) | 558.23 | 357 | 157 | 288 | — |
| Chemical Formula (7) | 608.74 | 349 | 143 | 207 | 368 |
| Chemical Formula (8) | 773.94 | 360 | 201 | 300 | 512 |
| Chemical Formula (9) | 773.94 | —^{b} | —^{b} | —^{b} | 422 |
| Chemical Formula (10) | 443.54 | 220 | 87 | — | 355 |

^{a}Decomposition temperature with 5% weight loss;
^{b}Not detected

As shown in Table 1, the thermal decomposition temperatures of Chemical Formula (1) to Chemical Formula (10) are all above 220° C. This suggests that their structures, characterized by multiple benzene ring arrangements, contribute to a rigid framework, providing excellent thermal stability during heating, without undergoing thermal decomposition at elevated temperatures.

The Electrochemical Properties of Compounds 1 to 10 (Chemical Formula (1) to Chemical Formula (10)) are Summarized in Table 2.

TABLE 2

| | E_{DPV}^{ox} | E_{DPV}^{re} | | | |
|---|---|---|---|---|---|
| | (V | (V | | | |
| | versus | versus | ^{a} E_{HOMO} | ^{b} E_{LUMO} | ^{c} E_{g} |
| Compound | Fc⁺/Fc) | Fc⁺/Fc) | (eV) | (eV) | (eV) |
| Chemical Formula (1) | 0.8805 | −2.282 | −6.068 | −2.701 | 3.367 |
| Chemical Formula (2) | 0.7885 | −2.330 | −5.589 | −2.656 | 2.933 |
| Chemical Formula (3) | 0.81 | −2.40 | −5.76 | −2.60 | 3.17 |
| Chemical Formula (4) | 0.80 | −2.24 | −5.76 | −2.74 | 3.02 |
| Chemical Formula (5) | 0.740 | −2.236 | −5.689 | −2.743 | 2.946 |
| Chemical Formula (6) | 0.723 | −2.264 | −5.668 | −2.717 | 2.951 |
| Chemical Formula (7) | 0.76 | −2.41 | 5.71 | 2.58 | 3.13 |
| Chemical Formula (8) | 0.710 | −2.39 | 5.65 | 2.60 | 3.05 |
| Chemical Formula (9) | 0.77 | −2.33 | 5.72 | 2.66 | 3.06 |
| Chemical Formula (10) | 0.647 | −2.24 | 5.57 | 2.73 | 2.84 |

^{a} E_{HOMO} = −1.2 × (E_{DPV}^{ox} − E^{Fc+/Fc}) + (−4.8) eV
^{b} E_{LUMO} = −0.92 × (E_{DPV}^{re} − E^{Fc+/Fc}) + (−4.8) eV
^{c} E_{g} = E_{LUMO} − E_{HOMO} eV

As shown in Table 2, compounds 1 to 10 (Chemical Formula (1) to Chemical Formula (10)) exhibit energy levels that are well-matched with other layer materials.

The Photophysical Properties of Compounds 1 to 10 (Chemical Formula (1) to Chemical Formula (10)) are Summarized in Tables 3, 4-1, 4-2, 5 and 6.

TABLE 3

| | λ_{abs}^{1, 2} | λ_{PL}^{1, 2} | λ^{abs}ₒₙₛₑₜ² | E_{g}^{1, 2} | HOMO^{1, 2} | LUMO^{1, 2} |
|---|---|---|---|---|---|---|
| Compound | [nm] | [nm] | [nm] | [eV] | [eV] | [eV] |
| Chemical | 346/344 | 419/458 | 374/408 | 3.32/3.04 | −5.857/— | −2.701/— |
| Formula (1) | | | | | | |
| Chemical | 355/360 | 431/451 | 390/414 | 3.18/3.02 | −5.746/— | −2.656/— |
| Formula (2) | | | | | | |

¹Measured in Solution;
²Measured in solid thin film

The maximum absorption wavelengths for Chemical Formula (1) and Chemical Formula (2) are 346 nm and 355 nm, respectively, both attributed to the π→π* absorption of the pyrene group. The fluorescence at room temperature is observed at 419 nm and 431 nm, falling within the blue light range.

TABLE 4-1

| | | | λₘₐₓ^{FL}/λₘₐₓ^{LTFL}/ | | | Q. Y.^{Dope}/ |
|---|---|---|---|---|---|---|
| | λₘₐₓ^{Abs, a} | λₒₙₛₑₜ^{Abs, b} | λₒₙₛₑₜ^{LTPH, c} | E_{g}^{d} | E_{T}^{e} | Q.Y.^{f} |
| Solution | (nm) | (nm) | (nm) | (eV) | (eV) | (%) |
| Chemical | 340 | 379 | 415/389/584 | 3.27 | 2.12 | 78 |
| Formula (3) | | | | | | |
| Chemical | 347 | 379 | 404/392/598 | 3.27 | 2.07 | 80 |
| Formula (4) | | | | | | |

^{a}Maximum UV-visible absorption wavelength;
^{b}UV-visible absorption onset wavelength;
^{c}Room temperature maximum fluorescence emission wavelength/Low-temperature maximum fluorescence emission wavelength/Maximum phosphorescence emission wavelength at 77K;
^{d}E_{g} (eV) = 1240.8/λₒₙₛₑₜ^{Abs};
^{e}E_{T} (eV) = 1240.8/λₒₙₛₑₜ^{LTPH};
^{f}Relative quantum yield, with DPA as the reference, measured in toluene.

TABLE 4-2

| | λ^{PL} | λₒₙₛₑₜ^{Abs} | λ_{Peak}^{Abs} | PLQY^{nondoped/doped} | HOMO | LUMO |
|---|---|---|---|---|---|---|
| Solid State | (nm) | (nm) | (nm) | (%) | (eV) | (eV) |
| Chemical | 428 | 405 | 355 | 88.2/87.3 | −5.76 | −2.60 |
| Formula (3) | | | | | | |
| Chemical | 471 | 408 | 342 | 74.4/80 | −5.76 | −2.74 |
| Formula (4) | | | | | | |

TABLE 5

| | λₘₐₓ^{Abs} | λₒₙₛₑₜ^{Abs} | λₘₐₓ^{PL} | HOMO | LUMO | Eg | PLQY |
|---|---|---|---|---|---|---|---|
| Solutiom/Film | (nm) | (nm) | (nm) | (eV) | (eV) | (eV) | (%) |
| Chemical | 346/358 | 399/425 | 421/449 | 5.7/— | 2.7/— | 3.0/2.9 | 67/65 |
| Formula (5) | | | | | | | |
| Chemical | 344/350 | 396/417 | 414/447 | 5.7/— | 2.7/— | 3.0/3.0 | 74/58 |
| Formula (6) | | | | | | | |

TABLE 6

| | λₘₐₓ^{Abs} | λₒₙₛₑₜ^{Abs} | E_{g} | λₘₐₓ^{FL} | |
|---|---|---|---|---|---|
| | (nm) | (nm) | (eV) | (nm) | |
| | (sol/ | (sol/ | (sol/ | (sol/ | Q.Y (%) |
| Compounds | film) | film) | film) | film) | (sol/film) |
| Chemical | 339/351 | 373/407 | 3.29/− | 421/450 | 57/− |
| Formula (7) | | | | | |
| Chemical | 344 | 376 | 3.33 | 424 | 82 |
| Formula (8) | | | | | |
| Chemical | 337/340 | 375/406 | 3.33/− | 426/437 | 79/61 |
| Formula (9) | | | | | |
| Chemical | 344 | 377 | 3.29 | 411 | 66 |
| Formula (10) | | | | | |

From Table 3, it can be observed that both Chemical Formula (1) and Chemical Formula (2) exhibit prominent absorption peaks in the range of 300 to 350 nm in solution, corresponding to the π-π* absorption of the pyrene group in the compounds. The maximum UV-visible absorption wavelengths for these compounds fall between 344 to 355 nm, showing a redshift of approximately 10 to 20 nm compared to the reference material Pyrene. This shift is likely attributed to the conjugation extension between the pyrene group and the central benzene ring, resulting in lower-energy absorption. In the room temperature fluorescence spectra (FL), Chemical Formula (1) and Chemical Formula (2) exhibit significant redshifts compared to the reference material Pyrene, shifting from 391 nm to 419 nm and 431 nm, respectively. This is likely due to the conjugation extension between the pyrene group and the central benzene ring.

In the case of these compounds in thin film states, the maximum absorption peaks in the UV spectra exhibit only slight redshifts, with redshift magnitudes all below 10 nm. However, in the FL spectra, more significant redshifts of 20 to 39 nm are observed. Similar phenomena have been noted in many other pyrene-based emitter materials, which may be attributed to the stacking of pyrene groups between molecules and a more coplanar configuration of molecules in the thin film state, resulting in conjugation extension. Among these compounds, Chemical Formula (1) shows the most substantial redshift, up to 39 nm, likely due to the tight arrangement of pyrene groups between molecules. Conversely, Chemical Formula (2), with a less dense arrangement and a more twisted structure, exhibits a smaller redshift of 20 nm, reaching 451 nm. The larger steric hindrance and structural distortion of Chemical Formula (2) reduce molecular aggregation and maintain a non-coplanar configuration, preventing excessive conjugation extension while preserving its high-energy blue emission and high fluorescence quantum efficiency characteristics.

The energy levels of Chemical Formula (1) and Chemical Formula (2) are relatively close to the reference material Pyrene, indicating that E_{HOMO} and E_{LUMO} are located on the pyrene group. However, due to the presence of highly electronegative fluorine in the molecules of Chemical Formula (1), its oxidation and reduction potentials are higher, and the energy levels are lower. The influence on E_{HOMO} is more significant, resulting in a larger energy gap.

From Table 4-1, it is observed that the UV-visible spectrum of Chemical Formula (3) in solution shows a pronounced absorption peak in the wavelength range of 230-280 nm, attributed to the π-π* absorption of carbazole and pyrene group. Additionally, a weaker absorption peak at 300-350 nm is present, indicating n-π* electron transition absorption from the carbazole group. On the other hand, Chemical Formula (4) exhibits a strong absorption peak at 278 nm, attributed to localized π-π* absorption of benzimidazole and pyrene group, while longer-wavelength absorptions represent delocalized π-π* absorption. In the solution-state fluorescence (FL) spectrum, Chemical Formula (4) shows distinct vibrational modes compared to Chemical Formula (3), suggesting that the N-phenyl group on the benzimidazole moiety restrict structural vibrations or rotations at room temperature, resulting in a more rigid structure.

In the thin film state fluorescence emission spectrum (FL) (Table 4-2), Chemical Formula (4) exhibits a noticeable redshift trend compared to Chemical Formula (3), shifting to 471 nm. This redshift is attributed to molecular stacking in the solid state, where a higher degree of molecular orbital overlap results in more significant energy lowering, leading to a spectral redshift. Chemical Formula (3) also shows a slight redshift, with the emission wavelength shifting to 428 nm, suggesting a potentially lower degree of stacking in the thin film state.

The oxidation and reduction potentials of Chemical Formula (4) are similar to the reference material Pyrene, indicating that the pyrene group facilitates the transfer of both holes and electrons. For Chemical Formula (3), the oxidation potential is similar to that of the reference material NPC (N-phenylcarbazole). Calculations of EHOMO reveal values close to those of Pyrene and NPC, suggesting that EHOMO may be influenced by both. The reduction potential is similar to Pyrene. Based on these results, it is observed that the pyrene group has a lower energy gap, making it prone to governing the transfer of both electrons and holes.

From Table 5, it can be observed that Chemical Formula (5) and Chemical Formula (6) exhibit distinct absorption peaks in the range of 300 to 350 nm in solution, attributed to the π-π* absorption of the pyrene group in the compounds. The maximum ultraviolet-visible absorption wavelengths for both compounds fall between 344 and 346 nm, with Chemical Formula (5) at 346 nm and Chemical Formula (6) at 344 nm. Compared to the reference material Pyrene (334 nm), there is a redshift of approximately 10 to 20 nm, suggesting the formation of conjugated extension between the pyrene group and the central benzene ring, resulting in lower energy absorption. Additionally, it is noteworthy that Chemical Formula (6), compared to Chemical Formula (5), exhibits more pronounced vibrational structures in the absorption peak range of 300 to 350 nm. This is speculated to be due to the rigidity of the structure in Chemical Formula (6), where two methyl groups are present adjacent to the pyrene group. Therefore, more evident vibrational levels are observed. Both Chemical Formula (5) and Chemical Formula (6) also show several distinct absorption peaks in the range of 350 to 400 nm, originating from the π-π* absorption of the 9-phenanthrene groups in the compounds. The fluorescence spectra of Chemical Formula (5) and Chemical Formula (6) resemble that of the reference material DPA in terms of waveform and position. Therefore, it is inferred that the primary fluorescence emission comes from the phenanthrene moiety in the compounds, and there is no significant redshift observed, indicating that the conjugated extension of the phenanthrene moiety is not prominent.

In the thin film state, these compounds exhibit only a slight redshift in the maximum absorption peaks of the UV spectra, with Chemical Formula (5) at 358 nm and Chemical Formula (6) at 350 nm. The degree of redshift is less than 10 nm. In the fluorescence (FL) spectra, a more pronounced redshift is observed, with Chemical Formula (5) at 449 nm and Chemical Formula (6) at 447 nm, resulting in a shift difference of 20 to 39 nm. In many other luminescent materials based on pyrene group, similar phenomena are observed. This may be attributed to the stacking of pyrene groups between molecules and the tendency of molecules to adopt a more coplanar configuration in the thin film state, leading to the extension of conjugation.

The energy levels of Chemincal Structure (5) and Chemincal Structure (6) are similar to that of the reference material DPA, indicating that the highest occupied molecular orbital (E_{HOMO}) and the lowest unoccupied molecular orbital (E_{LUMO}) are located on the anthracene moiety. Due to the presence of the electron-rich pyrene group adjacent to it, there is a slight tendency for an increase in E_{LUMO}.

Chemincal Structure (7) and Chemincal Structure (9) exhibit distinct absorption peaks in the ultraviolet-visible (UV-vis) spectrum, with prominent peaks at 230-280 nm attributed to the π-π* absorption of the carbazole and pyrene group. Additionally, weaker absorption peaks at 300-350 nm are observed, likely associated with the n-π* electronic transition of the carbazole moiety. Chemincal Structure (7) shows a noticeable redshift in the fluorescence spectrum in the thin film state, which is a result of molecular stacking in the solid state. A higher degree of molecular orbital stacking leads to a greater energy decrease, causing a redshift in the spectrum. Chemincal Structure (9) also exhibits a slight redshift, suggesting a lower degree of stacking in the thin film state.

All four compounds exhibit electrochemical activity and demonstrate characteristics of oxidation and reduction. Due to the properties of the pyrene group, different molecular designs allow it to function as either an electron-withdrawing or electron-donating group. Chemincal Structure (7) and Chemincal Structure (9) have oxidation and reduction potentials similar to that of the reference material Pyrene, indicating that the pyrene group assists in the transfer of both holes and electrons.

The following content describes the efficiency performance of compounds 1 to 10 (Chemical Formula (1) to Chemical Formula (10)) when applied in organic light-emitting diodes.

The structure of the organic light-emitting diode consists of indium tin oxide (ITO)/(1,1-Bis[(di-4-tolylamino)phenyl]cyclohexane; TAPC): 40 nm/(tris(4-carbazoyl-9-ylphenyl)amine; TCTA): 10 nm/sensitizer layer: 17.5 (or 5) nm and/or luminescent layer: 17.5 nm/(1,3,5-Tris(3-pyridyl-3-phenyl)benzene; TmPyPb): 45 nm/lithium fluoride (LiF): 0.8 nm/aluminum (Al): 120 nm. The following evaluations are conducted based on the produced organic light-emitting diodes, including the driving voltage, turn-on voltage, maximum current efficiency (CE, cd/A), and maximum power efficiency (PE, lm/W). The evaluation results are presented in Tables 7 to 15 below.

TABLE 7

| | | | | | | Half-life |
|---|---|---|---|---|---|---|
| | Driving | Turn-on | | | | operational |
| | Voltage | Voltage | C.E.ₘₐₓ | P.E.ₘₐₓ | EQEₘₐₓ | lifespan |
| Device | (V) | (V) | (cd/A) | (lm/W) | (%) | (minutes) |
| Chemical | 4.32 | 2.74 | 14.35 | 11.17 | 10.78 | 14 |
| Formula(1) | | | | | | |
| NAPN | 4.80 | 3.05 | 13.72 | 10.79 | 11.96 | — |
| Chemical | 4.57 | 2.99 | 14.16 | 10.83 | 11.56 | 28 |
| Formula(1)/ | | | | | | |
| NAPN | | | | | | |

Drving Voltage@ 10 mA/cm²;
Turn-on Voltage@1 nits;
operational lifespan@5000 nits

TABLE 8

| | | | | | | Half-life |
|---|---|---|---|---|---|---|
| | Driving | Turn-on | | | | operational |
| | Voltage | Voltage | C.E.ₘₐₓ | P.E.ₘₐₓ | EQEₘₐₓ | lifespan |
| Device | (V) | (V) | (cd/A) | (lm/W) | (%) | (minutes) |
| Chemical | 4.52 | 2.68 | 17.21 | 13.25 | 11.01 | 26 |
| Formula (2) | | | | | | |
| NAPN | 4.80 | 3.05 | 13.72 | 10.79 | 11.96 | — |
| Chemical | 4.64 | 2.99 | 14.85 | 11.26 | 11.81 | 41 |
| Formula | | | | | | |
| (2)/NAPN | | | | | | |

Driving Voltage @ 10 mA/cm²;
Turn-on Voltage @ 1 nits;
operational lifespan@5000 nits

TABLE 9

| | | | | | | Half-life |
|---|---|---|---|---|---|---|
| | Driving | Turn-on | | | | operational |
| | Voltage | Voltage | C.E.ₘₐₓ | P.E.ₘₐₓ | EQEₘₐₓ | lifespan |
| Device | (V) | (V) | (cd/A) | (lm/W) | (%) | (minutes) |
| Chemical | 4.66 | 3.00 | 9.77 | 12.37 | 9.13 | 13 |
| Formula (3) | | | | | | |
| NAPN | 4.54 | 3.00 | 11.20 | 14.23 | 10.78 | 55 |
| Chemical | 5.00 | 3.09 | 10.76 | 13.67 | 10.82 | 72 |
| Formula | | | | | | |
| (3)/NAPN | | | | | | |

Driving Voltage @ 10 mA/cm²;
Turn-on Voltage @ 1 nits;
operational lifespan@5000 nits

TABLE 10

| | | | | | | Half-life |
|---|---|---|---|---|---|---|
| | Driving | Turn-on | | | | operational |
| | Voltage | Voltage | C.E.ₘₐₓ | P.E.ₘₐₓ | EQEₘₐₓ | lifespan |
| Device | (V) | (V) | (cd/A) | (lm/W) | (%) | (minutes) |
| Chemical | 4.44 | 2.69 | 11.09 | 11.82 | 7.97 | 191 |
| Formula (4) | | | | | | |
| NAPN | 4.53 | 3.00 | 11.20 | 14.23 | 10.78 | 55 |
| Chemical | 4.36 | 2.74 | 14.02 | 16.87 | 11.69 | 269 |
| Formula | | | | | | |
| (4)/NAPN | | | | | | |

Driving Voltage @ 10 mA/cm²;
Turn-on Voltage @ 1 nits;
operational lifespan@5000 nits

TABLE 11

| | | | | | | Half-life |
|---|---|---|---|---|---|---|
| | Driving | Turn-on | | | | operational |
| | Voltage | Voltage | C.E.ₘₐₓ | P.E.ₘₐₓ | EQEₘₐₓ | lifespan |
| Device | (V) | (V) | (cd/A) | (lm/W) | (%) | (minutes) |
| Chemical | 4.13 | 17560 | 15.01 | 11.25 | 12.94 | 26 |
| Formula (6) | | | | | | |
| NAPN | 4.62 | 11970 | 15.32 | 12.06 | 13.18 | — |
| DMPPP/ | 4.50 | 19310 | 18.73 | 14.73 | 15.48 | 52 |
| Chemical | | | | | | |
| Formula (6) | | | | | | |

Driving Voltage @ 10 mA/cm²;
Turn-on Voltage @ 1 nits;
operational lifespan@5000 nits

TABLE 12

| | Driving | Turn-on | | | | operational |
|---|---|---|---|---|---|---|
| | Voltage | Voltage | C.E.ₘₐₓ | P.E.ₘₐₓ | EQEₘₐₓ | lifespan |
| Device | (V) | (V) | (cd/A) | (lm/W) | (%) | (minutes) |
| Chemical | 4.3 | 3.1 | 11.11 | 8.70 | 8.0 | 6 |
| Formula (7) | | | | | | |
| NAPN | 4.7 | 3.0 | 15.32 | 12.06 | 13.2 | — |
| Chemical | 4.5 | 3.0 | 15.68 | 12.33 | 12.1 | 8 |
| Formula | | | | | | |
| (7)/NAPN | | | | | | |

Driving Voltage @ 10 mA/cm²;
Turn-on Voltage @ 1 nits;
operational lifespan@5000 nits, attenuates to 70%

TABLE 13

| | Driving | Turn-on | | | | operational |
|---|---|---|---|---|---|---|
| | Voltage | Voltage | C.E.ₘₐₓ | P.E.ₘₐₓ | EQEₘₐₓ | lifespan |
| Device | (V) | (V) | (cd/A) | (lm/W) | (%) | (minutes) |
| Chemical | 4.51 | 2.8 | 16.16 | 14.51 | 10.7 | 32 |
| Formula (8) | | | | | | |
| NAPN | 4.7 | 3.0 | 15.32 | 12.06 | 13.2 | — |
| Chemical | 4.6 | 2.9 | 16.73 | 13.16 | 12.6 | 74 |
| Formula | | | | | | |
| (8)/NAPN | | | | | | |

Driving Voltage @ 10 mA/cm²;
Turn-on Voltage @ 1 nits;
operational lifespan@5000 nits, attenuates to 70%

TABLE 14

| | Driving | Turn-on | | | | operational |
|---|---|---|---|---|---|---|
| | Voltage | Voltage | C.E.ₘₐₓ | P.E.ₘₐₓ | EQEₘₐₓ | lifespan |
| Device | (V) | (V) | (cd/A) | (lm/W) | (%) | (minutes) |
| Chemical | 4.3 | 2.9 | 15.04 | 13.53 | 9.4 | 13 |
| Formula (9) | | | | | | |
| NAPN | 4.7 | 3.0 | 15.32 | 12.06 | 13.2 | — |
| Chemical | 4.5 | 2.9 | 15.95 | 12.55 | 12.1 | 8 |
| Formula | | | | | | |
| (9)/NAPN | | | | | | |

Driving Voltage @ 10 mA/cm²;
Turn-on Voltage @ 1 nits;
operational lifespan@5000 nits, attenuates to 70%

TABLE 15

| | Driving | Turn-on | | | | operational |
|---|---|---|---|---|---|---|
| | Voltage | Voltage | C.E.ₘₐₓ | P.E.ₘₐₓ | EQEₘₐₓ | lifespan |
| Device | (V) | (V) | (cd/A) | (lm/W) | (%) | (minutes) |
| Chemical | 4.4 | 3.1 | 13.68 | 9.56 | 9.3 | 8 |
| Formula (10) | | | | | | |
| NAPN | 4.7 | 3.0 | 15.32 | 12.06 | 13.2 | — |
| Chemical | 4.7 | 3.0 | 18.19 | 14.31 | 16.1 | 52 |
| Formula | | | | | | |
| (10)/NAPN | | | | | | |

Driving Voltage @ 10 mA/cm²;
Turn-on Voltage @ 1 nits;
operational lifespan@5000 nits, attenuates to 70%

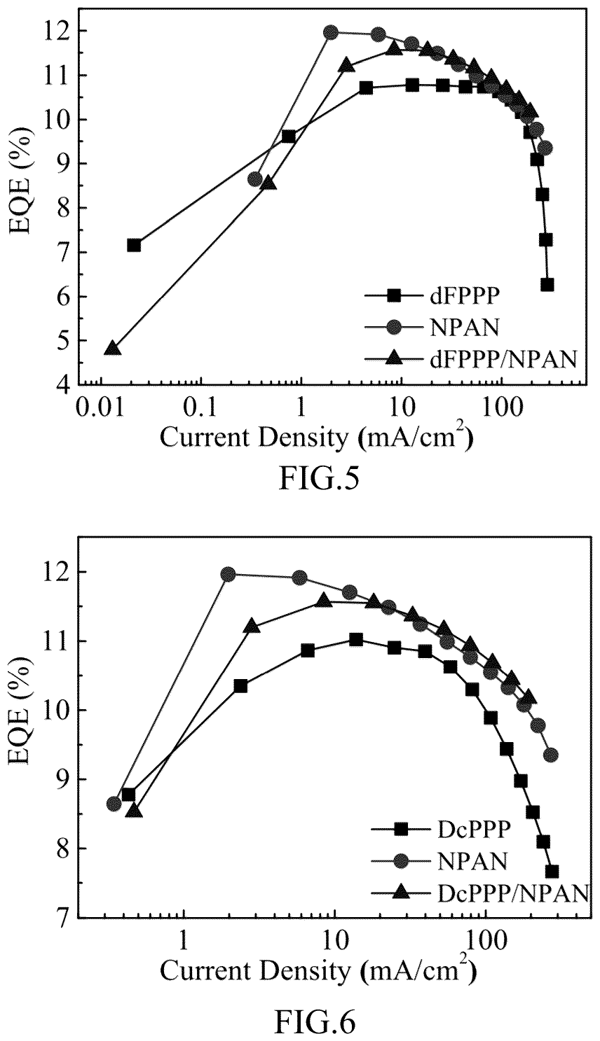

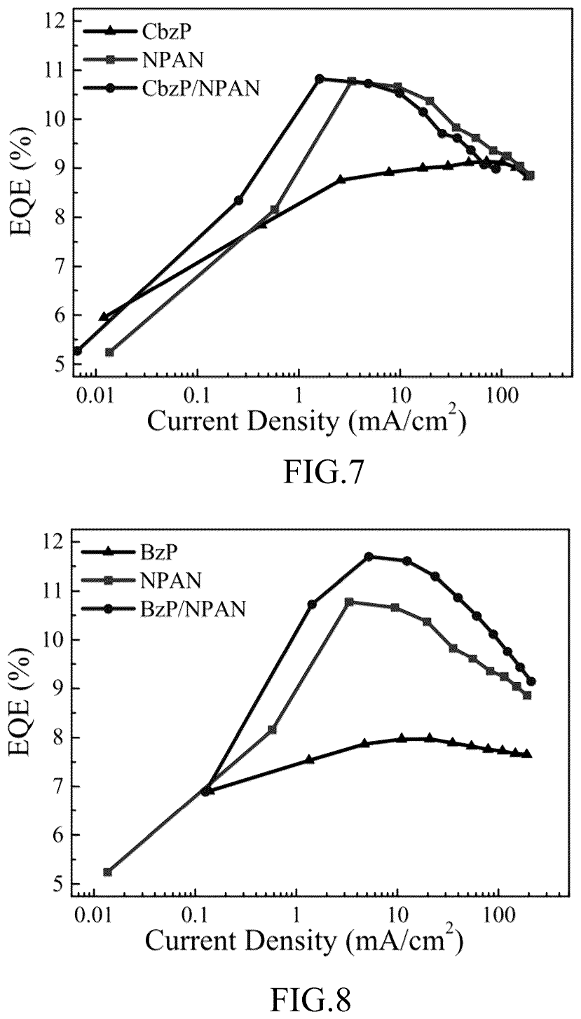

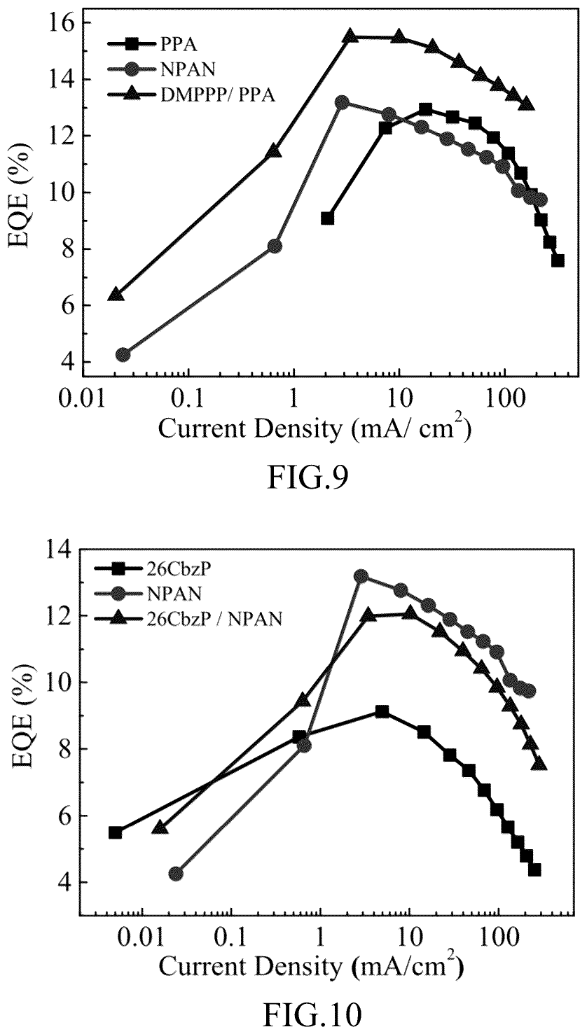

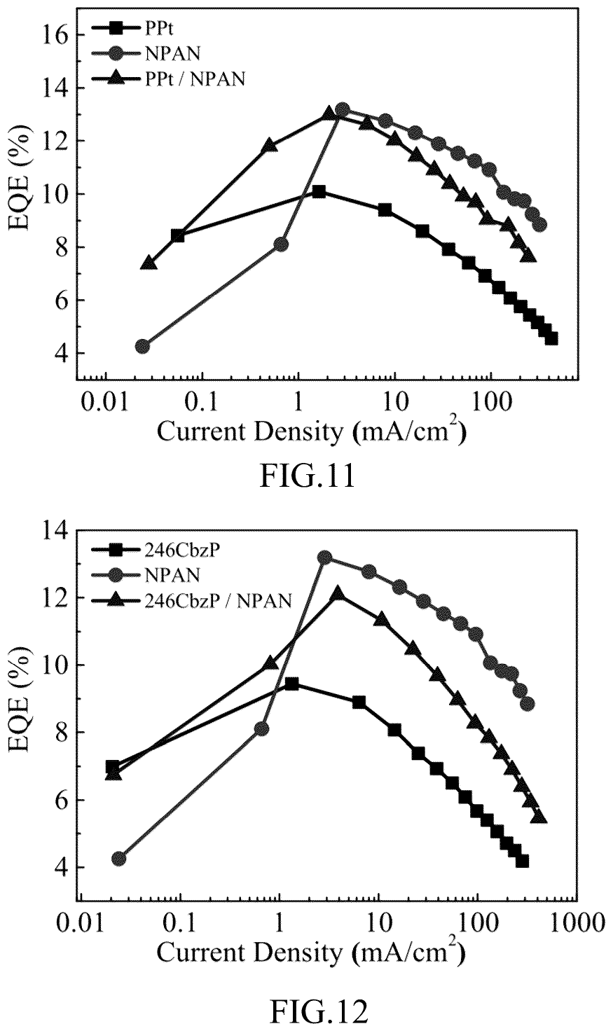

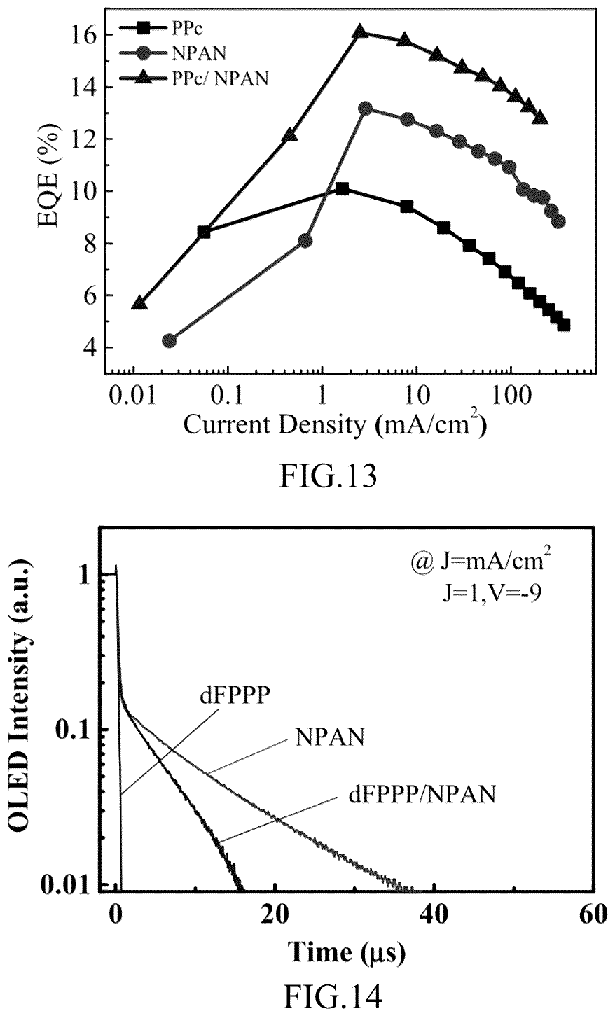

Meanwhile, as shown in FIG. 5, which illustrates external quantum efficiency (EQE)—current density curves for a comparative example using Chemical Formula (1) (represented by curve dFPPP), a comparative example using NAPN (represented by curve NAPN), and an experimental example with Chemical Formula (1) as the sensitizer layer and NAPN as the luminescent layer (represented by curve dFPPP/NAPN). As shown in FIG. 5, organic light-emitting diodes equipped with a sensitizer layer exhibit superior external quantum efficiency. Similarly, FIGS. 6 to 13 also depict external quantum efficiency (EQE)—current density curves for Chemical Formula (2) to Chemical Formula (10) as the sensitizer layer, revealing similar findings

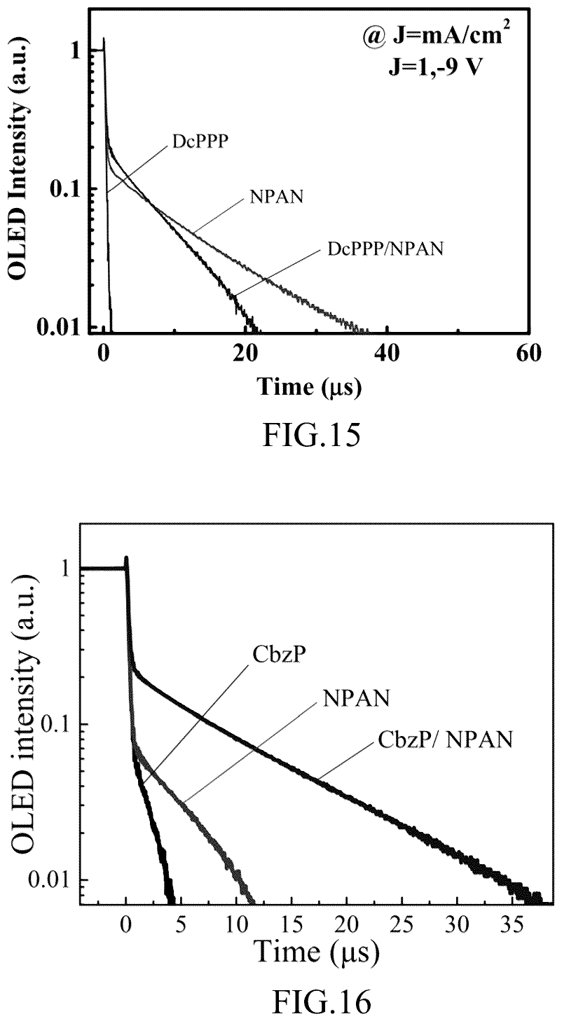

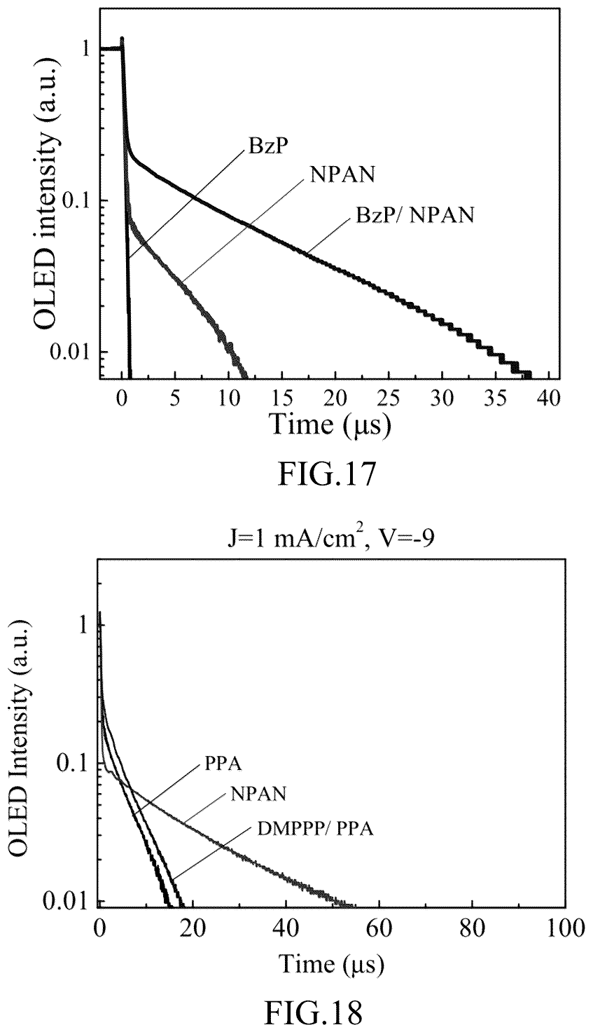

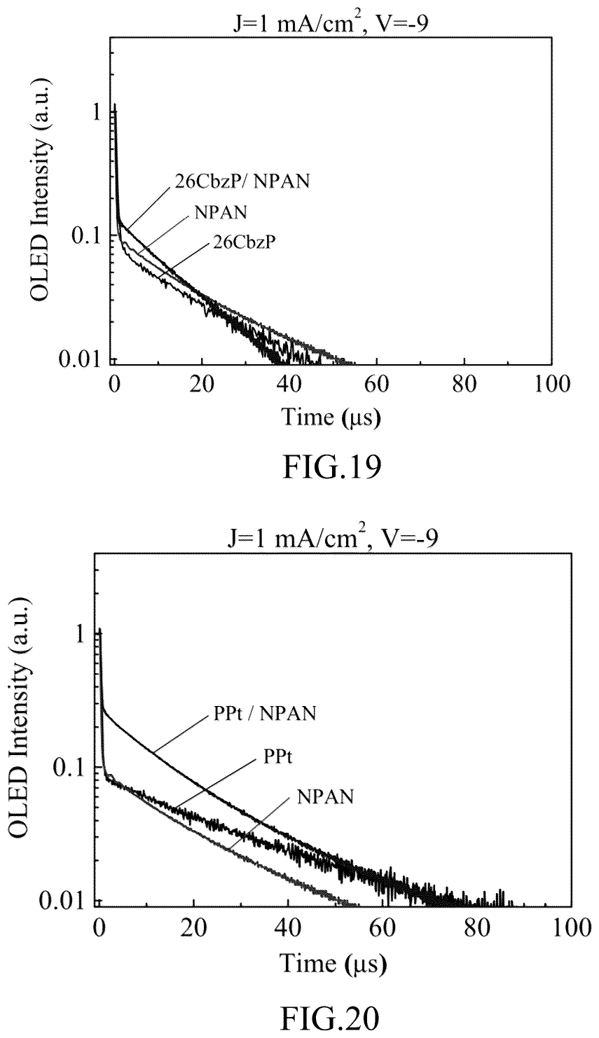

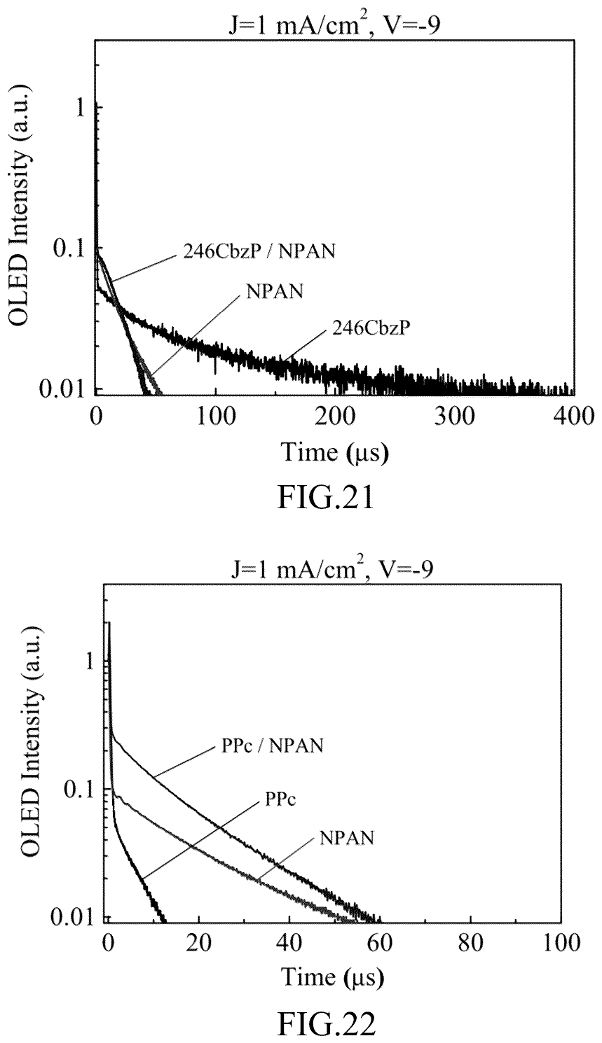

Furthermore, FIGS. 14 to 22 illustrate the time-resolved electroluminescence characteristics of organic light-emitting diodes. According to FIGS. 14 to 22, it can be observed that, after turning off the applied voltage at zero seconds, the organic light-emitting diode equipped with a sensitizer layer exhibits a complete luminescence duration in the microsecond range. Additionally, the delay percentage (triplet state percentage) is higher compared to using only the luminescent layer (without a sensitizer layer). This indicates that incorporating a sensitizer layer can effectively enhance the utilization efficiency of triplet states.

Compared to prior art, the external quantum efficiency (10.8%˜16.1%) of the blue organic light-emitting diodes fabricated with the materials of the present invention surpasses the reported efficiency in the prior arts (˜4%). Additionally, using the same structure, the efficiency of the devices produced surpasses that (15.4%) of the currently reported world-record blue OLEDs (DOI: https://doi.org/10.21203/rs.3.rs-994123/v1). The device efficiency for the Chemical Formula (10)/NPAN combination, as shown in Table 15, can reach 16.1%, making it the highest external quantum efficiency blue OLED employing triplet-triplet annihilation. This accomplishment aligns with the primary goal of developing new materials in this invention. In terms of functional group selection and positional connectivity, these materials, compared to traditional commercial materials and the previously used DMPPP, enhance the photoemissive quantum efficiency, electron and hole transport properties, and triplet-triplet annihilation upconversion efficiency, thereby boosting device efficiency.

In addition, besides the external quantum efficiency of the devices, these novel molecules possess larger molecular weights, offering the potential to enhance the thermal stability of the materials. There is a prospect of extending the operational lifespan of the devices, especially during high-brightness and high-temperature operations. Taking the example of the previously used material DMPPP in prior technologies, due to the lower molecular weight and stronger intermolecular forces, coupled with the absence of electron-hole transport functional groups and a lower material thermal decomposition temperature, the operational lifespan of the device is easily constrained by this layer. Therefore, the present invention addresses these issues by developing numerous materials with higher molecular weights.

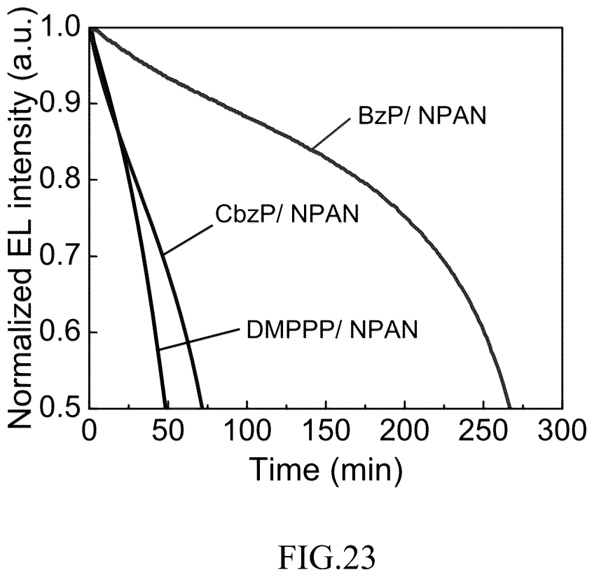

As shown in FIG. 23, which serves as evidence from the embodiments. When using the CbzP and BzP compounds, each modified with electron and hole functional groups as proposed by the present invention, under the initial brightness condition of 5000 nits, the half-life operational lifespan of the device significantly improves compared to the prior art where DMPPP is used as the sensitizer layer (CbzP: 72 mins, BzP: 269 mins, DMPPP: 49 mins).

In summary, the present invention utilizes organic electroluminescent materials containing at least pyrene group as the sensitizer layer, positioning it as the primary site for the combination of positive and negative polarons. This arrangement generates sensitizer layer triplet excitons to induce the triplet-triplet annihilation upconversion mechanism in the luminescent layer. Consequently, the triplet energy from the luminescent layer contributes to the emission of the organic light-emitting diode. In this embodiment, the sensitizer layer serves the role of a recombination zone, reducing the probability of high-energy polarons and excitons combining in the luminescent layer. Additionally, the triplet energy in the sensitizer layer is effectively utilized. As a result, the operational lifespan of the organic light-emitting diode is effectively extended, while simultaneously enhancing its efficiency.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

1. An organic electroluminescent material containing at least one pyrene group, used as a sensitizer layer in an organic light-emitting diode, comprising a structure of the following General Formula (1): 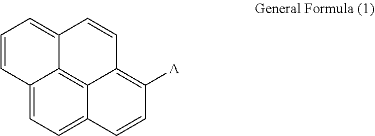
wherein A is selected from the group consisting of General Formula (2), a carbazole group, and a substituted benzimidazole group, 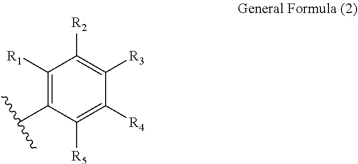
wherein, when R₂ and R₅ are each independently selected from the group consisting of halogen, boron, nitrogen, phosphorus, oxygen, and sulfur, R₃ is a pyrene group, and R₁ and R₄ are each hydrogen,
wherein, when R₂ and R₅ are each a carbazole group, R₃ is a pyrene group, and R₁ and R₄ are each hydrogen,
wherein, when R₃ is 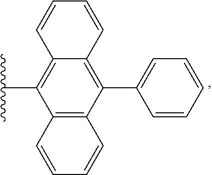 [SMILES: *c1c2ccccc2c(-c2ccccc2)c2ccccc12]
R₁, R₂, R₄, and R₅ are each hydrogen,
wherein, when R₁ and R₅ are each alkyl, R₃ is 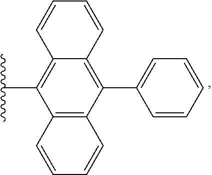 [SMILES: *c1c2ccccc2c(-c2ccccc2)c2ccccc12]
and R₂ and R₄ are each hydrogen,
wherein, when R₁ and R₅ are each a carbazole group, R₂, R₃, and R₄ are each hydrogen,
wherein, when R₃ is 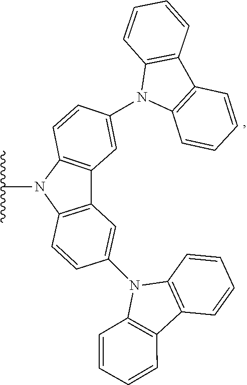 [SMILES: *n1c2ccc(-n3c4ccccc4c4ccccc43)cc2c2cc(-n3c4ccccc4c4ccccc43)ccc21]
R₁, R₂, R₄ and R₅ are each hydrogen,
wherein, when R₁, R₃, and R₅ are each a carbazole group, R₂ and R₄ are each hydrogen,
wherein, when R₃ is a carbazole group, R₁, R₂, R₄, and R₅ are each hydrogen.

2. The organic electroluminescent material according to claim 1, wherein the substituted benzimidazole group is represented as

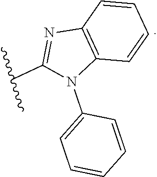 [SMILES: *c1nc2ccccc2n1-c1ccccc1]

3. The organic electroluminescent material according to claim 1, wherein the alkyl is a substituted straight-chain alkyl with a carbon number of 1 to 6, an unsubstituted straight-chain alkyl with a carbon number of 1 to 6, a substituted branched alkyl with a carbon number of 3 to 6, or an unsubstituted branched alkyl with a carbon number of 3 to 6.

4. The organic electroluminescent material according to claim 1, wherein the organic electroluminescent material containing the at least one pyrene group has a structure represented by the Chemical Formulas (1) to (10):

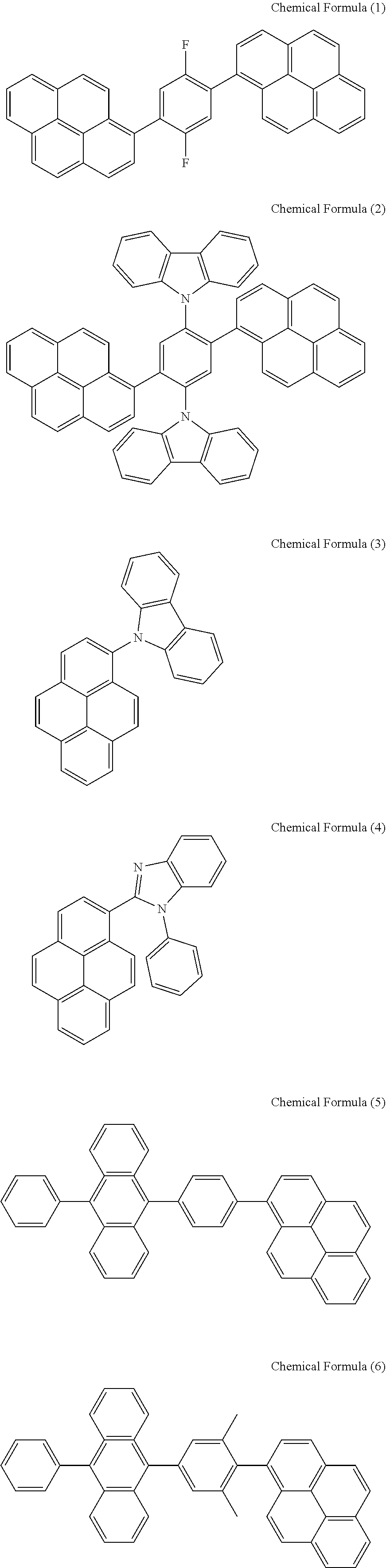

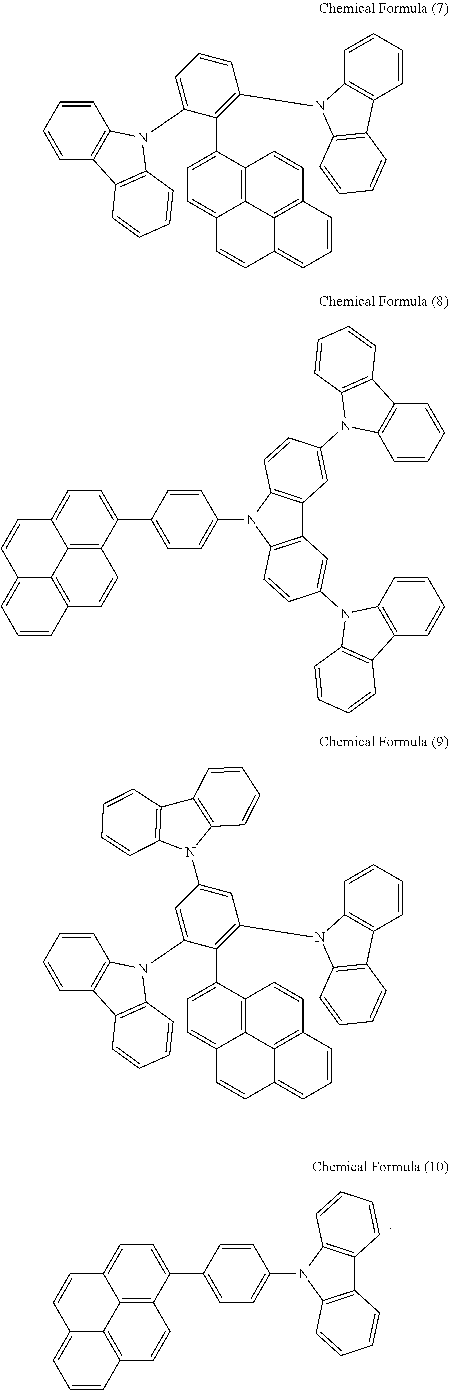 [SMILES: c1cc(-n2c3ccccc3c3ccccc32)c(-c2ccc3ccc4cccc5ccc2c3c45)c(-n2c3ccccc3c3ccccc32)c1 ; c1cc2ccc3ccc(-c4ccc(-n5c6ccc(-n7c8ccccc8c8ccccc87)cc6c6cc(-n7c8ccccc8c8ccccc87)ccc65)cc4)c4ccc(c1)c2c34 ; c1cc2ccc3ccc(-c4c(-n5c6ccccc6c6ccccc65)cc(-n5c6ccccc6c6ccccc65)cc4-n4c5ccccc5c5ccccc54)c4ccc(c1)c2c34 ; c1cc2ccc3ccc(-c4ccc(-n5c6ccccc6c6ccccc65)cc4)c4ccc(c1)c2c34]

5. The organic electroluminescent material according to claim 1, wherein the organic electroluminescent material containing the at least one pyrene group is a blue fluorescent material.

6. An organic light-emitting diode, comprising:
an anode;
a cathode; and
a luminescent layered structure, disposed between the anode and the cathode, wherein the luminescent layered structure comprises a luminescent layer and a sensitizer layer, the sensitizer layer comprises an organic electroluminescent material containing at least one pyrene group comprising a structure of the following General Formula (1): 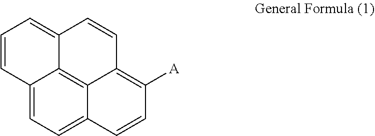
wherein A is selected from the group consisting of General Formula (2), a carbazole group, and a substituted benzimidazole group, 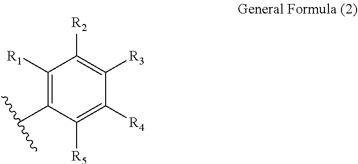
wherein, when R₂ and R₅ are each independently selected from the group consisting of halogen, boron, nitrogen, phosphorus, oxygen, and sulfur, R₃ is a pyrene group, and R₁ and R₄ are each hydrogen,
wherein, when R₂ and R₅ are each a carbazole group, R₃ is a pyrene group, and RI and R₄are each hydrogen,
wherein, when R₃ is 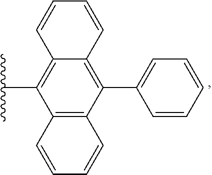 [SMILES: *c1c2ccccc2c(-c2ccccc2)c2ccccc12]
R₁, R₂, R₄, and R₅ are each hydrogen,
wherein, when R₁ and R₅ are each alkyl, R₃ is 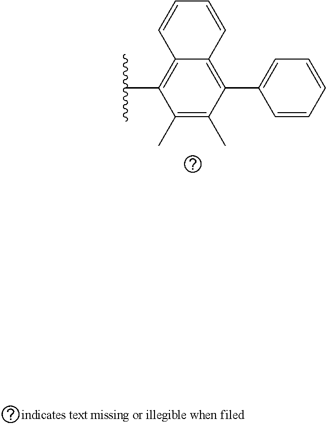 [SMILES: *c1c(C)c(C)c(-c2ccccc2)c2ccccc12]
, and R₂ and R₄ are each hydrogen,
wherein, when R₁ and R₅ are each a carbazole group, R₂, R₃, and R₄ are each hydrogen,
wherein, when R₃ is 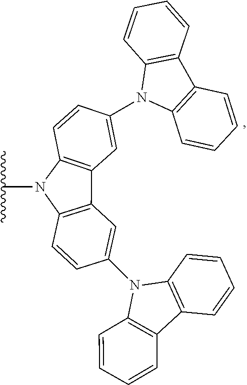 [SMILES: *n1c2ccc(-n3c4ccccc4c4ccccc43)cc2c2cc(-n3c4ccccc4c4ccccc43)ccc21]
R₁, R₂, R₄ and R₅ are each hydrogen,
wherein, when R₁, R₃, and R₅ are each a carbazole group, R₂ and R₄ are each hydrogen,
wherein, when R₃ is a carbazole group, R₁, R₂, R₄, and R₅ are each hydrogen.

7. The organic light-emitting diode according to claim 6, wherein the substituted benzimidazole group is represented as

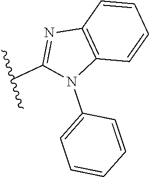 [SMILES: *c1nc2ccccc2n1-c1ccccc1]

8. The organic light-emitting diode according to claim 6, wherein the alkyl is a substituted straight-chain alkyl with a carbon number of 1 to 6, an unsubstituted straight-chain alkyl with a carbon number of 1 to 6, a substituted branched alkyl with a carbon number of 3 to 6, or an unsubstituted branched alkyl with a carbon number of 3 to 6.

9. The organic light-emitting diode according to claim 6, wherein the organic electroluminescent material containing the at least one pyrene group has a structure represented by the Chemical Formulas (1) to (10):

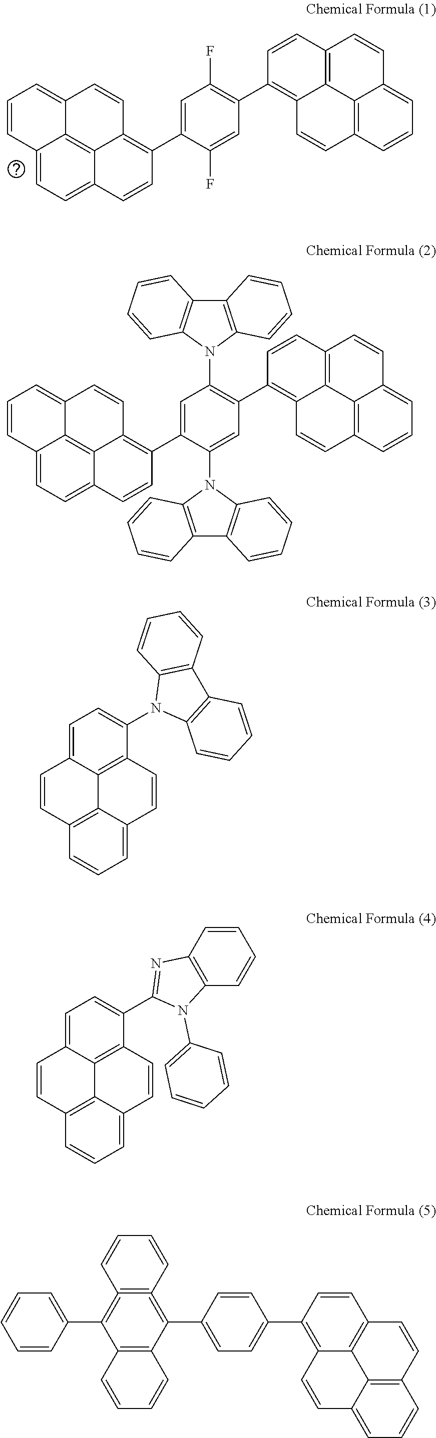

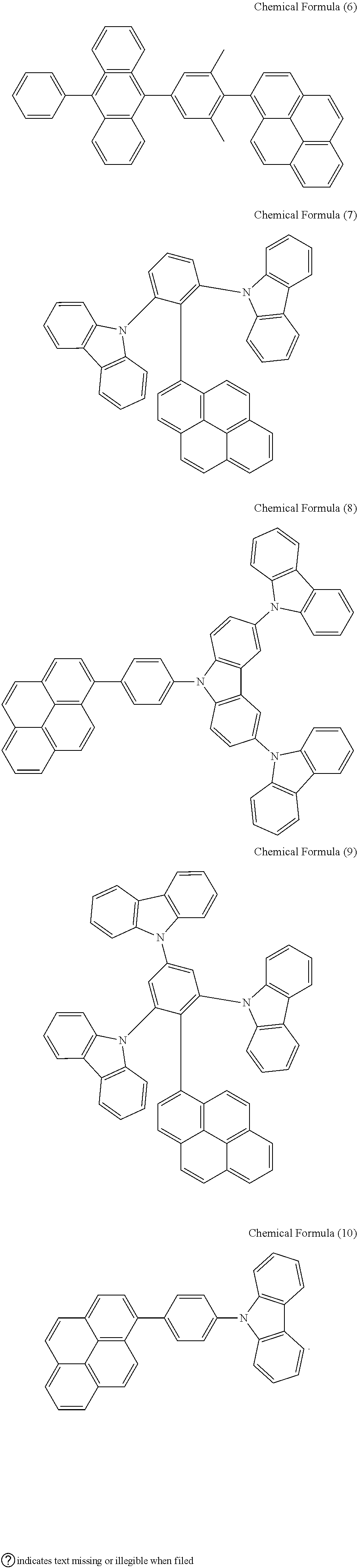

10. The organic light-emitting diode according to claim 6, wherein the luminescent layer comprises a luminescent-layer ground state, a luminescent-layer singlet state, and a luminescent-layer triplet state, two times of the luminescent-layer triplet state is higher than the luminescent-layer singlet state, the sensitizer layer includes a sensitizer-layer triplet state, the sensitizer-layer triplet state is positioned between the luminescent-layer singlet state and the luminescent-layer triplet state, molecules of the sensitizer layer at the sensitizer-layer triplet state transfer energy to molecules of the luminescent layer at the luminescent-layer triplet state and triggers triplet-triplet annihilation upconversion in the luminescent layer such that the luminescent layer emits light of a first color.

11. The organic light-emitting diode according to claim 10, wherein the sensitizer layer further comprises a sensitizer-layer singlet state and a sensitizer-layer ground state, in which the molecules of the sensitizer layer at the sensitizer-layer singlet state returns to the sensitizer-layer ground state and emits light of a second color.

12. The organic light-emitting diode according to claim 6, further comprising:
a hole transport layer disposed between the anode and the luminescent layered structure; and
an electron transport layer disposed between the cathode and the luminescent layered structure.

13. The organic light-emitting diode according to claim 6, wherein the sensitizer layer is an electron transport layer, the organic light-emitting diode further comprises a hole transport layer disposed between the anode and the luminescent layered structure.

14. The organic light-emitting diode according to claim 6, wherein the sensitizer layer is a hole transport layer, the organic light-emitting diode further comprises an electron transport layer disposed between the cathode and the luminescent layered structure.

15. The organic light-emitting diode according to claim 6, further comprising:
a barrier layer disposed between the sensitizer layer and the luminescent layer, wherein the barrier layer has a barrier-layer singlet state and a barrier-layer triplet state, the barrier-layer singlet state is higher than the luminescent-layer singlet state, and the barrier-layer triplet state is higher than the luminescent-layer triplet state.
